(19) United States
(12) Patent Application Publication
(10) Pub. No.: US 2026/0313944 A1
(43) Pub. Date: Oct. 8, 2026

(54) MULTIGATE DEVICE AND METHOD OF FABRICATION THEREOF

(71) Applicant: Taiwan Semiconductor Manufacturing Company, Ltd., Hsin-Chu (TW)

(72) Inventor: Ka-Hing Fung, Hsinchu (TW)

(21) Appl. No.: 19/305,293

(22) Filed: Aug. 20, 2025

Related U.S. Application Data
(60) Provisional application No. 63/782,905, filed on Apr. 3, 2025.

(51) Int. Cl. H10D 30/00; H10D 30/01; H10D 30/43; H10D 62/10; H10D 64/01; H10D 84/01; H10D 84/85

(52) U.S. Cl. CPC H10D 30/502; H10D 30/014; H10D 30/0191; H10D 30/43; H10D 62/121; H10D 64/017; H10D 84/0167; H10D 84/017; H10D 84/0179; H10D 84/851

(57) ABSTRACT

An exemplary device structure includes a semiconductor layer extending along a first direction between a first source/drain and a second source/drain. The semiconductor layer may be disposed over a semiconductor base. The device structure further includes a gate disposed between the first source/drain and the second source/drain. The gate is disposed over and engages the channel layer, and the gate extends along a second direction that is different than the first direction. The gate further extends along a third direction through the channel layer, and the third direction is different than the first direction and the second direction. In some embodiments, the gate may engage four sidewalls of the semiconductor layer. In some embodiments, the semiconductor layer is a ring-shaped semiconductor layer, and the semiconductor layer may surround a portion of the gate extending therethrough. In some embodiments, the semiconductor layer is a segmented channel layer.

This is a non-provisional application of and claims benefit of U.S. Provisional Patent Application Ser. No. 63/782,905, filed Apr. 3, 2025, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component that can be created using a fabrication process) has decreased. This scaling down process generally provides benefits by increasing production efficiency and lowering associated costs. Such scaling down has also increased the complexity of processing and manufacturing ICs, and for these advances to be realized, similar developments in IC materials and manufacturing are needed.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A-1E are various views of a device, in portion or entirety, having a segmented channel according to various aspects of the present disclosure.

FIG. 2, FIG. 3A, FIG. 3B, and FIG. 4 are diagrammatic cross-sectional views depicting different configurations of the device 100 of FIG. 1A, in portion or entirety, according to various aspects of the present disclosure.

FIGS. 5A-5Q and FIGS. 6A-6Q are diagrammatic cross-sectional views of a device, such as the device of FIGS. 1A-1E, in portion or entirety, at various stages of a fabrication process according to various aspects of the present disclosure.

FIGS. 7A-7M and FIGS. 8A-8M are diagrammatic cross-sectional views of a device, such as the device of FIGS. 1A-1E, in portion or entirety, at various stages of another fabrication process according to various aspects of the present disclosure.

FIGS. 9A-9F are diagrammatic cross-sectional views of a device, such as the device of FIGS. 1A-1E, in portion or entirety, at a channel cut stage of a fabrication process, such as that of FIGS. 5A-5Q and FIGS. 6A-6Q and/or FIGS. 7A-7M and FIGS. 8A-8M, according to various aspects of the present disclosure.

FIGS. 10A-10D are diagrammatic cross-sectional views of a device, such as the device of FIGS. 1A-1E, in portion or entirety, at a device isolation stage of a fabrication process, such as that of FIGS. 5A-5Q and FIGS. 6A-6Q and/or FIGS. 7A-7M and FIGS. 8A-8M, according to various aspects of the present disclosure.

FIG. 11 is a diagrammatic top view of a device layout, in portion or entirety, which may include the device of FIGS. 1A-1E, according to various aspects of the present disclosure.

FIGS. 12-17 are diagrammatic top views of channel cut layouts, in portion or entirety, that may be implemented at a channel cut stage of fabricating a device, such as associated with the fabrication processes of FIGS. 5A-5Q and FIGS. 6A-6Q and/or FIGS. 7A-7M and FIGS. 8A-8M, according to various aspects of the present disclosure.

FIG. 18A, FIG. 18B, FIG. 19A, and FIG. 19B are diagrammatic cross-sectional views of a device, in portion or entirety, that may include transistors having segmented channels, such as a transistor of the device of FIGS. 1A-1E and transistors having non-segmented channels, according to various aspects of the present disclosure.

### DETAILED DESCRIPTION

The present disclosure is generally directed to multigate devices (e.g., fin-like field effect transistors (FinFETs), gate-all-around (GAA) transistors (e.g., nanowire transistors or nanosheet transistors), fork-sheet transistors, or the like) and methods of fabrication.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Furthermore, when a number or a range of numbers is described with “about,” “approximate,” “substantially,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−20% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Multigate devices include a gate structure that extends, partially or fully, around a channel region to provide access to a channel region on at least two sides. One such multigate device is a gate-all around (GAA) device, which includes channel layers (regions) that are vertically or horizontally stacked and suspended in a manner over a substrate that allows a gate stack to wrap around (or surround) and engage the channel layers. The channel layers extend between a source region and a drain region (e.g., epitaxial source/drains), and voltage can be applied to the gate stack, the source region, and/or the drain region to control flow of current between the source region and the drain region. GAA devices can significantly increase contact area between the gate stack and the channel regions, which may decrease subthreshold swing (SS), decrease short channel effects (SCEs), increase drive current, and/or improve channel control compared to other multigate devices, such as fin-like field effect transistors (FinFETs).

The present disclosure proposes multigate devices and methods for fabricating the multigate devices that may reduce short channel effects, enable gate length reduction, enable channels with smaller width to height ratios, enable greater source/drain volume, improve multigate device performance, other improvements, or combinations thereof. Such improvements may be provided by segmenting a larger channel structure (e.g., a nanosheet) into smaller channel structures (e.g., nanowires), which may be connected and/or stitched together. Segmenting the larger channel structure into smaller channel structures may provide more sides and/or shorter sides for engagement by a gate, which may improve gate control and reduce short channel effects. Since forming a larger channel and subsequently segmenting it into smaller channel structures is easier than initially forming smaller channel structures, the proposed segmentation is seamlessly integrated into multigate device fabrication processes without significant increases in manufacturing complexity, time, costs, or combinations thereof. In some embodiments, such segmentation is introduced before or during a gate replacement process. In some embodiments, the segmentation provides the smaller channel structures with width/height ratios that may maximize gate control and thus improve short channel effect control. In some embodiments, the improved gate control (and thus improved short channel effect control) provided by the disclosed segmentation may compensate for any degradation of short channel effect control that may arise as gate lengths scale for advanced nodes (e.g., gate lengths less than about 20 nm). The disclosed multigate devices and fabrication techniques described herein may thus improve device performance, as described herein. Different embodiments may have different advantages, and no particular advantage is required of any embodiment.

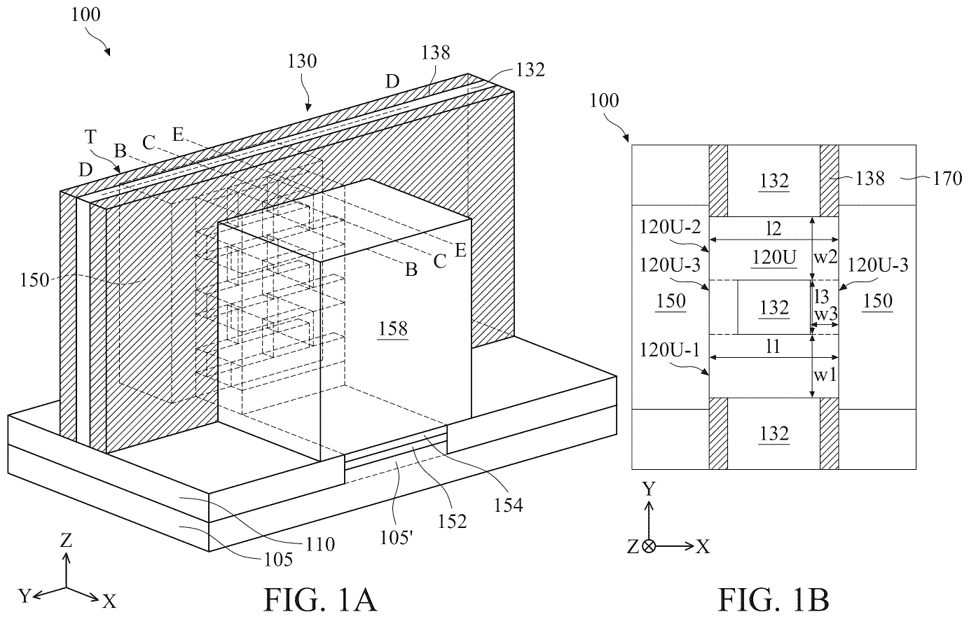

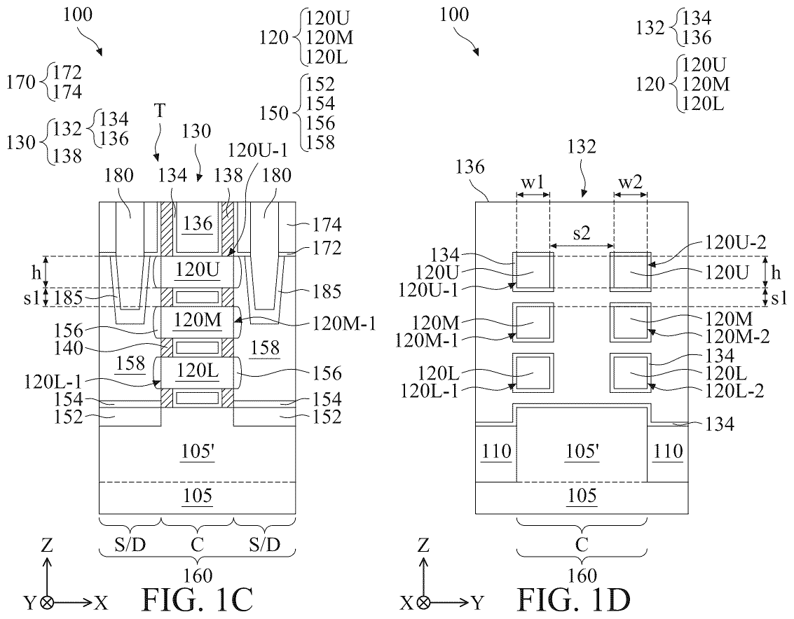

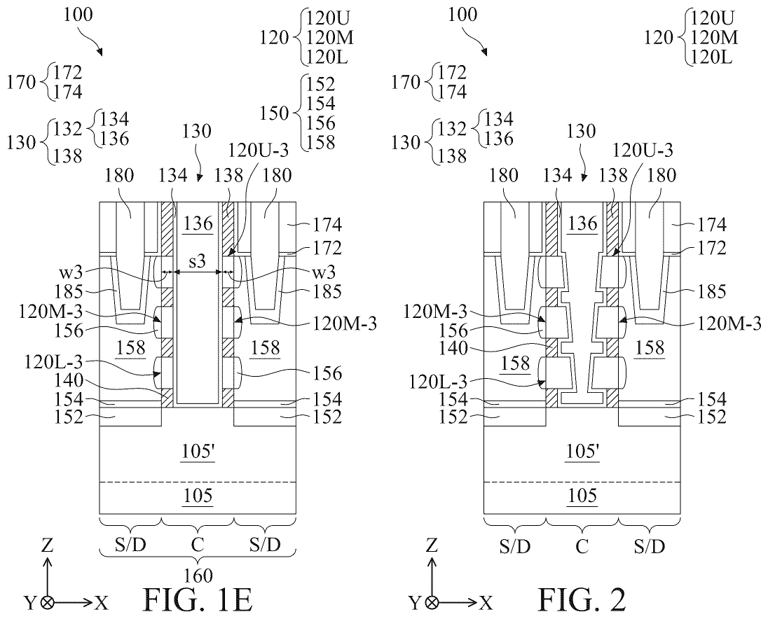

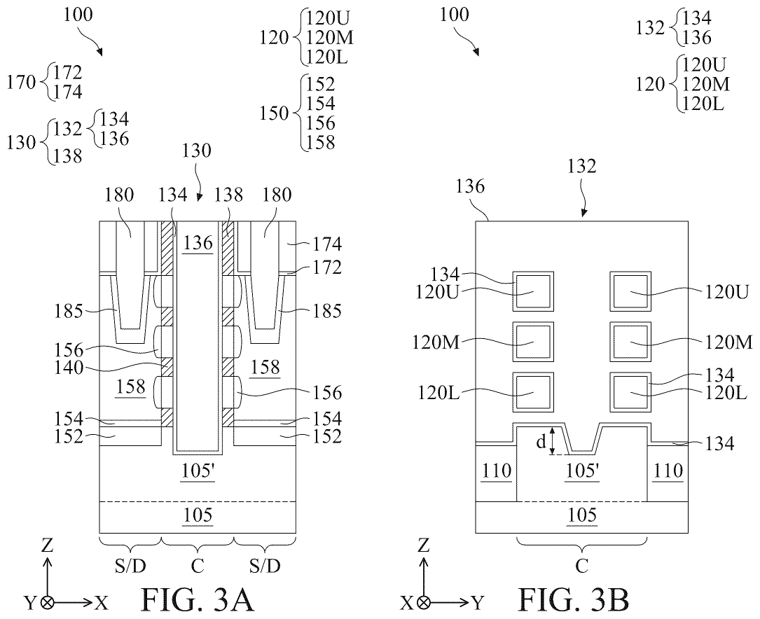

FIGS. 1A-1E are various views of a device 100, in portion or entirety, according to various aspects of the present disclosure. FIG. 1A is a diagrammatic perspective view of device 100, in portion or entirety, according to various aspects of the present disclosure. FIG. 1B is a diagrammatic top view of device 100, in portion or entirety, along line B-B of FIG. 1A (e.g., through a top channel of device 100) according to various aspects of the present disclosure. FIG. 1C is a diagrammatic cross-sectional view of device 100, in portion or entirety, along line C-C of FIG. 1A according to various aspects of the present disclosure. FIG. 1D is a diagrammatic cross-sectional view of device 100, in portion or entirety, along line D-D of FIG. 1A according to various aspects of the present disclosure. FIG. 1E is a diagrammatic cross-sectional view of device 100, in portion or entirety, along line E-E of FIG. 1A according to various aspects of the present disclosure. FIG. 2, FIG. 3A, FIG. 3B, and FIG. 4 are diagrammatic cross-sectional views depicting different configurations of device 100, in portion or entirety, according to various aspects of the present disclosure. FIG. 2 is a cross-sectional view of device 100, in portion or entirety, along line E-E of FIG. 1A according to various aspects of the present disclosure. FIG. 3A is a cross-sectional view of device 100, in portion or entirety, along line E-E of FIG. 1A according to various aspects of the present disclosure. FIG. 3B is a cross-sectional view of device 100, in portion or entirety, along line D-D of FIG. 1A according to various aspects of the present disclosure. FIG. 4 is a cross-sectional view of device 100, in portion or entirety, along line D-D of FIG. 1A according to various aspects of the present disclosure. FIGS. 1A-1E, FIG. 2, FIG. 3A, FIG. 3B, and FIG. 4 are discussed concurrently herein for ease of description and understanding. FIGS. 1A-1E, FIG. 2, FIG. 3A, FIG. 3B, and FIG. 4 have been simplified for the sake of clarity to better understand the inventive concepts of the present disclosure. Additional features may be added in device 100, and some of the features described below may be replaced, modified, or eliminated in other embodiments of device 100.

Device 100 may include at least one transistor T, such as a gate-all-around (GAA) transistor (i.e., a transistor having a gate that at least partially surrounds a suspended channel(s) (for example, a nanowire(s), a nanosheet(s), a nanobar(s), or the like) that extends between source/drains). Device 100 may be included in a microprocessor, a memory, other integrated circuit (IC) device, or combinations thereof. In some embodiments, device 100 is a portion of an IC chip, a system on chip (SoC), or portion thereof, and device 100 may include various passive electronic devices and/or active electronic devices, such as resistors, capacitors, inductors, diodes, p-type field effect transistors (PFETs), n-type FETs (NFETs), metal-oxide-semiconductor FETs (MOSFETs), complementary MOS (CMOS) transistors, bipolar junction transistors (BJTs), laterally diffused MOS (LDMOS) transistors, high voltage transistors, high frequency transistors, other suitable components, or combinations thereof.

Device 100 may include a substrate 105, a protrusion 105′, isolation structures 110 (also referred to as substrate isolation structures), semiconductor layers 120, and a gate structure 130. Gate structure 130 may include a gate stack 132 (e.g., a gate dielectric 134 and a gate electrode 136) and gate spacers 138. Device 100 may further include inner spacers 140 and source/drain structures 150. Each source/drain structure 150 may be multilayered, including, for example, a semiconductor layer 152, an insulator layer 154, a semiconductor layer 156, and a semiconductor layer 158. An active region 160 of device 100 extends lengthwise along an x-direction (i.e., length is along the x-direction, width is along a y-direction, and height is along a z-direction), and active region 160 may be oriented substantially parallel to other active regions. Active region 160 includes at least one channel region (C), source region, and drain region. Source regions and drain regions may collectively be referred to as source/drain regions (S/D). In some embodiments, source/drain structures 150 may be formed in and/or provide source/drain regions of active region 160, and semiconductor layers 120, which extend between source/drain regions, may be formed in and/or provide channel regions of active region 160.

In some embodiments, such as depicted, transistor T includes a channel (e.g., semiconductor layers 120), source/drains (e.g., source/drain structures 150), and a gate (e.g., gate stack 132). Gate stack 132 is disposed between source/drain structures 150 (e.g., along an x-direction), and inner spacers 140 may be disposed between gate stack 132 and source/drain structures 150. Gate stack 132 engages the channel (e.g., semiconductor layers 120), and the channel extends between the source/drains (e.g., source/drain structures 150) (e.g., along the x-direction). In the depicted embodiment, transistor T is a GAA transistor, and gate stack 132 surrounds the channel (e.g., semiconductor layers 120). In some embodiments, transistor T is a p-type transistor. In some embodiments, transistor T is an n-type transistor.

Substrate 105, protrusion 105′, and semiconductor layers 120 include an elementary semiconductor, such as silicon and/or germanium; a compound semiconductor, such as silicon carbide, gallium arsenide, gallium phosphide, indium phosphide, indium arsenide, indium antimonide, or combinations thereof; an alloy semiconductor, such as SiGe, GaAsP, AlInAs, AlGaAs, GaInAs, GaInP, GaInAsP, or combinations thereof; or combinations thereof. In some embodiments, substrate 105 is a semiconductor-on-insulator substrate, such as a silicon-on-insulator (SOI) substrate, a silicon germanium-on-insulator (SGOI) substrate, or a germanium-on-insulator (GOI) substrate. In some embodiments, substrate 105 is a silicon substrate, and protrusion 105′ may be formed of the same semiconductor material as substrate 105 (e.g., silicon) or a different semiconductor material (e.g., silicon germanium). In some embodiments, protrusion 105′ is a patterned, projecting portion and/or extension of substrate 105, and protrusion 105′ may be referred to as a substrate extension, a substrate fin portion, a fin portion, an etched substrate portion, etc. Semiconductor layers 120 may be formed of the same semiconductor material or a different semiconductor material than substrate 105. In the depicted embodiments, semiconductor layers 120 are silicon layers or silicon germanium layers.

Substrate 105 (and protrusion 105′) may include various doped regions, such as p-type doped regions (e.g., p-wells), n-type doped regions (e.g., n-wells), or combinations thereof. N-type doped regions include n-type dopants, such as phosphorus, arsenic, other n-type dopant, or combinations thereof. P-type doped regions include p-type dopants, such as boron, indium, gallium, other p-type dopant, or combinations thereof. In some embodiments, the doped regions include p-type dopants and n-type dopants. The doped regions may provide a p-well structure, an n-well structure, a dual-well structure, a raised structure, other suitable structure, or combinations thereof. In some embodiments, substrate 105 and/or protrusion 105′ may include an n-well and/or a p-well. For example, substrate 105 and/or protrusion 105′ may include a p-well in an n-type transistor region and an n-well in a p-type transistor region. In some embodiments, semiconductor layers 120 include n-type dopant and/or p-type dopant.

Isolation structures 110 may be formed over substate 105 and adjacent to and/or around protrusion 105′. In some embodiments, active region 160 is separated from other active regions and/or device regions by isolation structures 110. Isolation structures 110 may electrically isolate active region 160, such as protrusion 105′ and/or source/drain structures 150 thereof, from other active regions. Isolation structures 110 include silicon oxide, silicon nitride, silicon oxynitride, other suitable isolation material (including, silicon, oxygen, nitrogen, carbon, other suitable isolation constituent, or combinations thereof), or combinations thereof. Isolation structures 110 may have a multilayer structure. For example, isolation structures 110 may include a bulk dielectric (e.g., an oxide layer) over a dielectric liner(s) (e.g., silicon nitride, silicon oxide, silicon oxynitride, silicon oxycarbonitride, or combinations thereof). In another example, isolation structures 110 may include a bulk dielectric over a doped liner(s), such as a boron silicate glass (BSG) liner and/or a phosphosilicate glass (PSG) liner. Dimensions and/or characteristics of isolation structures 110 may be configured to provide shallow trench isolation (STI) structures, deep trench isolation (DTI) structures, local oxidation of silicon (LOCOS) structures, other suitable isolation structures, or combinations thereof.

Semiconductor layers 120 are stacked vertically (e.g., along the z-direction) and suspended over substrate 105 and/or protrusion 105′, and semiconductor layers 120, or portions thereof, may provide channels of transistor T. In the depicted embodiment, three semiconductor layers 120—upper semiconductor layer 120U, middle semiconductor layer 120M, and lower semiconductor layer 120L—are vertically stacked over protrusion 105′ and extend lengthwise between source/drain source/drain structures 150. For example, semiconductor layers 120 extend along the x-direction, having a length along the x-direction, a width along the y-direction, and a height along the z-direction. Device 100 and/or transistor T may be configured with different numbers of semiconductor layers 120. For example, a semiconductor layer stack (also referred to as a channel stack) may include two to six semiconductor layers 120.

Gate structure 130 is disposed over channel region (C) of active region 160 (e.g., a channel stack formed by semiconductor layers 120) and between respective source/drain regions (S/D) of active region 160 (e.g., source/drain structures 150). Gate structure 130 extends lengthwise along a direction different than (e.g., orthogonal to) the lengthwise direction of active region 160. For example, gate structure 130 extends along the y-direction, having a length along the y-direction, a width along the x-direction, and a height along the z-direction. Gate structure 130 may extend substantially parallel to other gate structures. As noted above, gate structure 300 includes gate stack 132 (e.g., gate dielectric 134 and gate electrode 136) and gate spacers 138. In FIG. 1C (e.g., the X-Z plane), gate structure 130 is disposed between source/drain structures 150, gate stack 132 is disposed on and engages tops and bottoms of semiconductor layers 120, and gate spacers 138 are disposed on topmost semiconductor layer 120 (e.g., semiconductor layer 120U). In FIG. 1D (e.g., the Y-Z plane), gate stack 132 is disposed over protrusion 105′, isolation structures 110, and semiconductor layers 120, and gate stack 132 at least wraps semiconductor layers 120. Gate stack 132 may be disposed on and engage tops, bottoms, and sidewalls of semiconductor layers 120 (e.g., gate stack 132 surrounds semiconductor layers 120). Gate stack 132 is thus disposed between semiconductor layer 120U and semiconductor layer 120M, semiconductor layer 120M and semiconductor layer 120L, and semiconductor layer 120L and protrusion 105′. In some embodiments, gate stack 132 may wrap protrusion 105′. For example, gate stack 132 is disposed on a top and sidewalls of protrusion 105′.

Stacking the channels (e.g., semiconductor layers 120) may increase device density and improve device performance. For example, configuring transistor T with stacked semiconductor layers 120 reduces an area consumed by transistor T, such that more transistors may fit into a given area, while also increasing effective channel width, thereby boosting transistor drive current. However, as device feature dimensions decrease to accommodate the higher device densities of scaled IC technology nodes, gate control has been observed to degrade, particularly as gate lengths decrease and channel width to height ratios increase, such that control of short channel effects has worsened in scaled devices.

The present disclosure proposes segmenting and/or cutting a larger channel structure (e.g., a nanosheet) into smaller channel structures (e.g., nanowires and/or nanobars) that may be stitched together, thereby improving performance of transistor T and/or device 100. In some embodiments, semiconductor layers 120 are segmented channels, and semiconductor layers 120 may have ring-shaped profiles, instead of sheet-shaped profiles. For example, semiconductor layer 120U includes a semiconductor segment 120U-1 extending lengthwise along the active region lengthwise direction (e.g., the x-direction), a semiconductor segment 120U-2 extending lengthwise along the active region lengthwise direction (e.g., the x-direction), and semiconductor segments 120U-3 extending lengthwise along the gate lengthwise direction (e.g., the y-direction) from semiconductor segment 120U-1 to semiconductor segment 120U-2; semiconductor layer 120M includes a semiconductor segment 120M-1 extending lengthwise along the active region lengthwise direction (e.g., the x-direction), a semiconductor segment 120M-2 extending lengthwise along the active region lengthwise direction (e.g., the x-direction), and semiconductor segments 120M-3 extending lengthwise along the gate lengthwise direction (e.g., the y-direction) from semiconductor segment 120M-1 to semiconductor segment 120M-2; and semiconductor layer 120L includes a semiconductor segment 120L-1 extending lengthwise along the active region lengthwise direction (e.g., the x-direction), a semiconductor segment 120L-2 extending lengthwise along the active region lengthwise direction (e.g., the x-direction), and semiconductor segments 120L-3 extending lengthwise along the gate lengthwise direction (e.g., the y-direction) from semiconductor segment 120L-1 to semiconductor segment 120L-2.

Semiconductor layer 120U and semiconductor layer 120M are separated by a spacing s1 (e.g., along the z-direction), semiconductor layer 120M and semiconductor layer 120L are separated by spacing s1, and semiconductor layer 120L and protrusion 105′ may be separated by spacing s1. Semiconductor segment 120U-1 and semiconductor segment 120U-2 are separated by a spacing s2 (e.g., along the y-direction); semiconductor segment 120M-1 and semiconductor segment 120M-2 are separated by spacing s2; and semiconductor segment 120L-1 and semiconductor segment 120L-2 are separated by spacing s2. Semiconductor segments 120U-3 are separated by a spacing s3 (e.g., along the x-direction), and semiconductor segments 120U-3 connect and/or stitch together semiconductor segment 120U-1 and semiconductor segment 120U-2. Semiconductor segments 120M-3 are separated by a spacing s3, and semiconductor segments 120M-3 connect and/or stitch together semiconductor segment 120M-1 and semiconductor segment 120M-2. Semiconductor segments 120L-3 are separated by spacing s3, and semiconductor segments 120L-3 connect and/or stitch together semiconductor segment 120L-1 and semiconductor segment 120L-2. In some embodiments, such as depicted, since semiconductor layer 120U has a substantially straight inner sidewall (e.g., formed by an inner sidewall of semiconductor segment 120U-1, an inner sidewall of semiconductor segment 120U-2, and inner sidewalls of semiconductor segments 120U-3), semiconductor layer 120M has a substantially straight inner sidewall (e.g., formed by an inner sidewall of semiconductor segment 120M-1, an inner sidewall of semiconductor segment 120M-2, and inner sidewalls of semiconductor segments 120M-3), and semiconductor layer 120L has a substantially straight inner sidewall (e.g., formed by an inner sidewall of semiconductor segment 120L-1, an inner sidewall of semiconductor segment 120L-2, and inner sidewalls of semiconductor segments 120L-3), spacing s2 and spacing s3 are substantially the same from a top to bottom of a channel structure of transistor T (e.g., semiconductor layers 120 thereof).

In some embodiments, such as depicted, since semiconductor layer 120U has a substantially straight inner sidewall and a substantially straight outer sidewall (e.g., formed by an outer sidewall of semiconductor segment 120U-1, an outer sidewall of semiconductor segment 120U-2, and outer sidewalls of semiconductor segments 120U-3), semiconductor layer 120M has a substantially straight inner sidewall and a substantially straight outer sidewall (e.g., formed by an outer sidewall of semiconductor segment 120M-1, an outer sidewall of semiconductor segment 120M-2, and outer sidewalls of semiconductor segments 120M-3), and semiconductor layer 120L has a substantially straight inner sidewall and a substantially straight outer sidewall (e.g., formed by an outer sidewall of semiconductor segment 120L-1, an outer sidewall of semiconductor segment 120L-2, and outer sidewalls of semiconductor segments 120L-3), widths of channel segments of the channel structure of transistor T are substantially the same from a top to bottom of the channel structure. For example, semiconductor segment 120U-1, semiconductor segment 120M-1, and semiconductor segment 120L-1 may have a width w1 (along the y-direction) and a length l1 (e.g., along the x-direction); semiconductor segment 120U-2, semiconductor segment 120M-2, and semiconductor segment 120L-2 may have a width w2 (along the y-direction) and a length l2 (e.g., along the x-direction); and semiconductor segments 120U-3, semiconductor segments 120M-3, and semiconductor segments 120L-3 may have a width w3 (e.g., along the x-direction) and a length l3 (e.g., along the y-direction). In some embodiments, width w1 is equal to width w2, and length l1 is equal to length l2. In some embodiments, width w1 is different than width w2 and/or length l1 is different than length l2. A sum of width w1, width w2, and length l3 (which may correspond with spacing s2) may be equal to a total width of active region 160 (e.g., along the x-direction).

Because semiconductor layers 120 are segmented to have ring-shaped profiles, gate stack 132 may extend through semiconductor layers 120, and gate stack 132 may engage more than an outer sidewall (or sidewalls) of semiconductor layers 120. For example, gate stack 132 may be disposed over and engage both an outer sidewall and an inner sidewall of semiconductor layers 120. In some embodiments, gate stack 132 is disposed on a top, a bottom, and four sidewalls (two of which may collectively provide an inner sidewall and two of which may collectively provide an outer sidewall) of semiconductor layers 120. As an example, gate stack 132 may engage an upper side, a lower side, a left side, and a right side of both semiconductor segment 120U-1 and semiconductor segment 120U-2; an upper side, a lower side, a left side, and a right side of both semiconductor segment 120M-1 and semiconductor segment 120M-2; and an upper side, a lower side, a left side, and a right side of both semiconductor segment 120L-1 and semiconductor segment 120L-2. The increased gate engagement (e.g., by configuring the channel structure with more sides, along with shorter sides) enables greater electrostatic gate control over semiconductor layer 120 and thus improved SCE control.

Further, because width w1 and width w2 are less than a total width of active region 160, width/height ratios of semiconductor layers 120 (e.g., channel segments thereof) are less than a width/height ratio of a non-segmented semiconductor layer 120 (e.g., having a width that is equal to the total width of active region 160), which may further improve gate control over the channel structure. For example, semiconductor layers 120 have a height h (e.g., along the z-direction), a ratio of width w1 to height h (i.e., w1/h) is less than a ratio of a total width of active region 160 to height h, and a ratio of width w2 to height h (i.e., w/h) is less than a ratio of a total width of active region 160 to height h. In some embodiments, the ratio of the total width of active region 160 to height h is greater than or equal to about 2. In some embodiments, w1/h is less than about 2 and greater than about 0.5 (i.e., 0.5<w1/h<2). For example, w1/h may be about 1. In some embodiments, w2/h is less than about 2 and greater than about 0.5 (i.e., 0.5<WU2/H<2). For example, w2/h may be about 1. Gate length scaling (e.g., to less than 20 nm (e.g., about 12 nm)), and corresponding decreases in source-drain separation, have been observed to reduce gate control over middles of channels, thereby worsening SCE control. Channels having width/height ratios that are too large (e.g., greater than or equal to 2) or too small (e.g., less than 0.5) may thus provide poorer gate control because such channel width/height ratios may result in channels (e.g., channel segments) having two of four sides (e.g., an upper side, a lower side, a right side, and a left side) that are too far in a middle of the channels, which may be difficult for gates to control at scaled dimensions. Since device performance may be dominated by these two sides (i.e., those closer to a middle of the channels), transistors configured with channels having width/height ratios less than 0.5 or greater than or equal to 2 may exhibit greater SCEs. In contrast, channels having width/height ratios greater than or equal to 0.5 and less than 2 maximize gate control, thereby minimizing SCEs, by enabling sufficient “gating” of the upper sides, the lower sides, the right sides, and the left sides of the channels.

Semiconductor segments of semiconductor layers 120 extending between source/drain structures 150 (e.g., semiconductor segment 120U-1, semiconductor segment 120U-2, semiconductor segment 120M-1, semiconductor segment 120M-2, semiconductor segment 120L-1, semiconductor segment 120L-2, or combinations thereof) may provide channels of transistor T. The semiconductor segments may have cylindrical-shaped profiles (and thus may provide transistor T with nanowires), quadrilateral-shaped profiles (and thus may provide transistor T with nanobars), or any other suitable shaped profile. In some embodiments, such as depicted, the semiconductor segments may be nanowires, and transistor T may be referred to as a nanowire transistor. In some embodiments, semiconductor layers 120 and/or semiconductor segments thereof have nanometer-sized dimensions and may be referred to as “nanostructures.” In some embodiments, semiconductor layers 120 and/or semiconductor segments have sub-nanometer dimensions and/or other suitable dimensions. In some embodiments, such as depicted, semiconductor layers 120 may be rectangular shaped rings. In some embodiments, semiconductor layers 120 may be circular shaped rings, rhombus shaped rings, trapezoidal shaped rings, polygon shaped rings, oval shaped rings, diamond shaped rings, hexagonal shaped rings, octagonal shaped rings, other suitably shaped rings, or combinations thereof.

In some embodiments, such as depicted in FIG. 2, semiconductor layers 120 may have tapered inner sidewalls and/or tapered outer sidewalls, such that spacing s2, spacing s3, width w1, width w2, width w3, or combinations thereof may be tapered (i.e., increase or decrease along a gate height direction (e.g., the z-direction)). In such embodiments, gate stack 132 may wrap channel connecting segments (e.g., semiconductor segments 120U-3, semiconductor segments 120M-3, semiconductor segments 120L-3, or combinations thereof), such as depicted. In some embodiments, such as depicted in FIG. 3A and FIG. 3B, gate stack 132 may extend into and/or penetrate protrusion 105′ and/or substrate 105. Such configuration may ease fabrication of device 100, for example, by enlarging an etch process window associated with a channel cut stage during fabrication of device 100 (e.g., which may involve forming a channel cut (i.e., segmenting semiconductor layers 120) that may subsequently be filled by gate stack 132). In some embodiments, gate stack 132 extends a distance d into protrusion 105′ and/or substrate 105. In some embodiments, distance d is less than about 20 nm. In some embodiments, such as depicted in FIG. 4, transistor T may include more than two channel segments. For example, semiconductor layer 120U may further include a semiconductor segment 120U-4 (which may be connected and/or stitched to semiconductor segment 120U-1 and/or semiconductor segment 120U-2 by semiconductor segments 120U-3); semiconductor layer 120M may further include a semiconductor segment 120M-4 (which may be connected and/or stitched to semiconductor segment 120M-1 and/or semiconductor segment 120M-2 by semiconductor segments 120M-3); and semiconductor layer 120L may further include a semiconductor segment 120L-4 (which may be connected and/or stitched to semiconductor segment 120L-1 and/or semiconductor segment 120L-2 by semiconductor segments 120L-3). The present disclosure contemplates various channel segmentation configurations.

Gate dielectric 134 includes at least one dielectric gate layer. In some embodiments, gate dielectric 134 includes an interfacial layer that includes a dielectric material, such as SiO₂, SiGeOₓ, HfSiO, SiON, other dielectric material, or combinations thereof. In some embodiments, gate dielectric 134 includes a high-k dielectric layer. The high-k dielectric layer includes a high-k dielectric material, which generally refers to dielectric materials having a dielectric constant that is greater than a dielectric constant of silicon dioxide (k≈3.9), such as HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TiO, TiO₂, LaO, LaSiO, LaO₃, La₂O₃, Ta₂O₃, Ta₂O₅, Y₂O₃, SrTiO₃, BaZrO, BaTiO₃ (BTO), (Ba, Sr)TiO₃ (BST), Si₃N₄, HfO₂-Al₂O₃, other high-k dielectric material, or combinations thereof. For example, gate dielectric 134 may include a hafnium-based oxide (e.g., HfO₂) layer and/or a zirconium-based oxide (e.g., ZrO₂) layer. In some embodiments, the interfacial layer and/or the high-k dielectric layer has a multilayer structure.

Gate electrode 136 is disposed over gate dielectric 134. Gate electrode 136 includes at least one electrically conductive gate layer. The electrically conductive gate layer includes an electrically conductive material, such as Al, Cu, Ti, Ta, W, Mo, Co, TaN, NiSi, CoSi, TiN, WN, TiAl, TiAlN, TaCN, TaC, TaSiN, other electrically conductive material, or combinations thereof. In some embodiments, gate electrode 136 includes a work function layer. The work function layer is a conductive layer tuned to have a desired work function, such as an n-type work function or a p-type work function. The work function layer includes work function metal(s) and/or alloys thereof, such as Ti, Ta, Al, Ag, Mn, Zr, W, Ru, Mo, TiC, TiAl, TiAlC, TiAlSiC, TaC, TaCN, TaSiN, TiSiN, TiN, TaN, TaSN, WN, WCN, ZrSi₂, MoSi₂, TaSi₂, NiSi₂, TaAl, TaAlC, TaSiAlC, TiAlN, or combinations thereof. In some embodiments, gate electrode 136 includes a bulk layer over the gate dielectric and/or the work function layer. The bulk layer includes a suitable conductive material, such as Al, W, Cu, Ti, Ta, TiN, TaN, polysilicon, other suitable metal(s) and/or alloys thereof, or combinations thereof. In some embodiments, gate electrode 136 includes a barrier (blocking) layer over the work function layer and/or the gate dielectric. The barrier layer includes a material that prevents or eliminates diffusion and/or reaction of constituents between adjacent layers and/or promotes adhesion between adjacent layers, such as between the work function layer and the bulk layer. In some embodiments, the barrier layer includes metal and nitrogen, such as titanium nitride, tantalum nitride, tungsten nitride, titanium silicon nitride, tantalum silicon nitride, or combinations thereof.

Gate spacers 138 are formed adjacent to and along sidewalls of gate stack 130. Gate spacers 138 include a dielectric material, which may include silicon, oxygen, carbon, nitrogen, other suitable dielectric constituent, or combinations thereof (e.g., silicon oxide, silicon nitride, silicon oxynitride, silicon carbide, silicon carbonitride, silicon oxycarbide, silicon oxycarbonitride, or combinations thereof). In some embodiments, gate spacers 138 have a multilayer structure, such as two or more dielectric layers having different compositions. In some embodiments, gate spacers 138 include more than one set of spacers, such as seal spacers, offset spacers, sacrificial spacers, dummy spacers, main spacers, or combinations thereof. In such embodiments, the various sets of spacers have different compositions.

Inner spacers 140 may be disposed under gate structure 130 (e.g., under gate spacers 138 thereof) and along sidewalls of gate stack 132. Inner spacers 140 are disposed between gate stack 132 and source/drain structures 150, between adjacent semiconductor layers 120, and between bottommost semiconductor layer 120 (e.g., semiconductor layer 120L) and protrusion 105′. Inner spacers 140 include a dielectric material that includes silicon, oxygen, carbon, nitrogen, or combinations thereof, such as silicon oxide, silicon nitride, silicon oxynitride, silicon carbide, silicon oxycarbonitride, etc. In some embodiments, inner spacers 140 include a low-k dielectric material. In some embodiments, dopants (e.g., p-type and/or n-type) are introduced into the dielectric material, and inner spacers 140 include doped dielectric material(s). In some embodiments, formation of inner spacers 140, including respective manufacturing steps associated therewith, is optional. That is, formation of inner spacers 140 may be omitted, such that inner spacers 140 may not exist in the depicted transistor of device 100.

Source/drain structures 150 include a semiconductor material, which may be doped with n-type dopants and/or p-type dopants. In some embodiments, source/drain structures 150 are formed by an epitaxy process, such that source/drain structures 150 include epitaxially grown/deposited semiconductor material and may be referred to as epitaxial source/drains. In some embodiments, source/drain structures 150 include silicon doped with carbon, phosphorous, arsenic, other n-type dopant, or combinations thereof. In some embodiments, source/drain structures 150 include silicon germanium or germanium doped with boron, other p-type dopant, or combinations thereof. In some embodiments, heavily doped source/drain (HDD) regions, lightly doped source/drain (LDD) regions, other doped regions, or combinations thereof are formed in source/drain structures 150. In some embodiments, the doped regions, such as LDD regions, may be disposed in and/or extend into channel regions, such as semiconductor layers 120. As used herein, source/drain region, source/drain, source/drain structure, epitaxial source/drain, epitaxial source/drain feature, etc. may refer to a source of device 100 and/or a transistor thereof, a drain of device 100 and/or a transistor thereof, or a source and/or a drain of multiple devices (including device 100) and/or of multiple transistors thereof.

Source/drain structures 150 may include a respective semiconductor layer 152, a respective insulator layer 154, a respective semiconductor layer 156, and a respective semiconductor layer 158. Semiconductor layers 152 are disposed on protrusion 105′ and/or substrate 105. In the depicted embodiment, semiconductor layers 152 include dopant-free semiconductor material (i.e., substantially free of n-type dopant and/or p-type dopant). For example, no intentional doping is performed when forming semiconductor layers 152, e.g., by an epitaxial growth process. Semiconductor layers 152 may thus provide high resistance paths at bottoms of source/drain structures 150, thereby hindering leakage current from flowing between source/drain structures 150 through protrusion 105′ and/or substrate 105. In some embodiments, the undoped semiconductor layers are formed of include silicon, germanium, silicon germanium, other suitable semiconductor materials, or combinations thereof. For example, semiconductor layers 152 may be dopant-free silicon layers or dopant-free silicon germanium layers.

Insulator layers 154 are disposed on semiconductor layers 152, and insulator layers 154 may be disposed between semiconductor layers 158 and semiconductor layers 152. Insulator layers 154 include an electrically insulating material, such as a dielectric material, that may also hinder unwanted leakage current from flowing between source/drain structures 150 (e.g., semiconductor layers 158 thereof) through protrusion 105′ and/or substrate 105. In some embodiments, insulator layers 154 include a silicon-comprising dielectric material, such as silicon nitride, silicon oxynitride, silicon oxycarbonitride, silicon oxycarbide, silicon carbonitride, other silicon-comprising dielectric material (which may include silicon and nitrogen, carbon, oxygen, other suitable dielectric constituent, or combinations thereof), or combinations thereof. In some embodiments, insulator layers 154 include a metal-comprising dielectric material, such as a metal oxide material (e.g., aluminum oxide and/or hafnium oxide) and/or a metal nitride material. In some embodiments, insulator layers 154 include a doped semiconductor material that includes an opposite type of dopant than semiconductor layers 158. For example, where source/drain structures 150 may belong to p-type transistors having p-type doped semiconductor layers, insulator layers 154 may include an n-type doped semiconductor material, such as phosphorous-doped silicon. In another example, where source/drain structures 150 may belong to n-type transistors having n-type doped semiconductor layers, insulator layers 154 may include p-doped semiconductor material, such as boron-doped silicon. In some embodiments, insulator layers 154, alone or in combination with semiconductor layers 152 (e.g., undoped semiconductor layers), may be referred to as bottom source/drain isolation.

Semiconductor layers 156 and semiconductor layers 158 are disposed over insulator layers 154 and are coupled to semiconductor layers 120. Semiconductor layers 156 may be disposed between semiconductor layers 158 and semiconductor layers 120. In the depicted embodiment, semiconductor layers 156 and semiconductor layers 158 include a semiconductor material (e.g., silicon, germanium, silicon germanium, other suitable semiconductor materials, or combinations thereof) that is doped with n-type dopants and/or p-type dopants. Semiconductor layers 156 and semiconductor layers 158 may have different compositions and/or different dimensions/configurations, and the different compositions may be achieved with different semiconductor materials, different dopants, different constituent atomic percentages, different dopant concentrations, or combinations thereof. For example, semiconductor layers 158 may be heavily doped semiconductor layers, and semiconductor layers 156 may be lightly doped semiconductor layers, where a dopant concentration of the heavily doped semiconductor layers is greater than a dopant concentration of the lightly doped semiconductor layers. In some embodiments, semiconductor layers 156 and semiconductor layers 158 may include silicon doped with different concentrations of carbon, phosphorous, arsenic, antimony, other n-type dopant, or combinations thereof. In another example, semiconductor layers 156 and semiconductor layers 158 may include silicon germanium doped with different concentrations of boron, gallium, other p-type dopant, or combinations thereof. In some embodiments, semiconductor layers 156 and semiconductor layers 158 include materials and/or dopants that provide desired tensile stress and/or compressive stress in the channel regions.

Device 100 may further include a dielectric layer 170, which may include a contact etch stop layer (CESL) 172 and an interlayer dielectric (ILD) layer 174. CESL 172 is disposed over gate structure 130 (e.g., gate spacers 138 thereof), source/drain structures 150, isolation structures 110, and substrate 105 (e.g., protrusion 105′ thereof). A composition of CESL 172 is different than a composition of ILD layer 174 to enable etching selectivity therebetween. In some embodiments, CESL 172 includes a silicon-comprising dielectric material. For example, CESL 172 includes silicon and nitrogen and/or carbon, such as silicon nitride, silicon carbide, silicon oxynitride, silicon oxycarbonitride, silicon carbonitride, silicon oxycarbide, other silicon-comprising dielectric material (which may include silicon and nitrogen, carbon, oxygen, other suitable dielectric constituent, or combinations thereof), or combinations thereof. In some embodiments, CESL 172 includes a metal-comprising dielectric material. For example, CESL 172 includes metal and oxygen, nitrogen, carbon, or combinations thereof, such as a metal oxide (e.g., aluminum oxide) and/or a metal nitride (e.g., aluminum nitride). The metal may be aluminum, hafnium, titanium, copper, manganese, vanadium, other suitable metal, or combinations thereof. In some embodiments, CESL 172 has a multilayer structure.

ILD layer 174 may include a silicon-and-oxygen-comprising dielectric material. For example, ILD layer 174 is a silicon oxide layer. In some embodiments, the silicon-and-oxygen-comprising dielectric material is a low-k dielectric material, which generally refers to a dielectric material having a dielectric constant less than a dielectric constant of silicon dioxide (k≈3.9). For example, ILD layer 174 may be a porous silicon oxide layer, which may have a dielectric constant less than about 2.5 (k≈2.5). In another example, ILD layer 174 may be a carbon-doped silicon oxide layer (e.g., an SiOC layer), which may have a dielectric constant less than about 2.5 (k≈2.5). In some embodiments, ILD layer 174 is a doped silicon oxide layer, such as a carbon-doped silicon oxide layer, a phosphorous-doped silicon oxide layer (e.g., PSG), a boron-doped silicon oxide layer (e.g., BSG), a boron-and-phosphorous-doped silicon oxide layer (e.g., BPSG), a fluorine-doped silicon oxide layer (e.g., FSG), other suitably doped silicon oxide layer, or combinations thereof. In some embodiments, ILD layer 174 is a tetraethylorthosilicate (TEOS)-formed oxide layer. In some embodiments, ILD layer 174 is a benzocyclobutene (BCB)-based dielectric layer. In some embodiments, ILD layer 174 has a multilayer structure.

Device 100 may further include source/drain contacts 180. Source/drain contacts 180 are disposed on and coupled to source/drain structures 150 (e.g., semiconductor layers 158 thereof), and source/drain contacts 180 extend through dielectric layer 170. In the depicted embodiment, source/drain contacts 180 extend into source/drain structure 150. Source/drain contacts 180 include an electrically conductive material, such as tungsten, ruthenium, cobalt, molybdenum, copper, aluminum, titanium, tantalum, iridium, palladium, platinum, nickel, tin, gold, silver, other suitable metal, alloys thereof, or combinations thereof. In some embodiments, source/drain contacts 180 are barrier-free/liner-free metal plugs, such as tungsten plugs, cobalt plugs, or ruthenium plugs. For example, each of source/drain contacts 180 may include a metal bulk layer, such as a tungsten plug, that abuts surrounding dielectric materials, such as ILD layer 174 and/or CESL 172. In some embodiments, source/drain contacts 180 include metal bulk layers and metal liner(s), where the metal liner(s) is between the metal bulk layers and surrounding dielectric materials (e.g., ILD layer 174 and/or CESL 172). In some embodiments, the metal liner(s) is between the metal bulk layers and source/drain structures 150 (e.g., semiconductor layers 185 thereof) and/or silicide layers 185. In some embodiments, the metal liner(s) includes tantalum, tantalum nitride, tantalum aluminum nitride, tantalum silicon nitride, tantalum carbide, titanium, titanium nitride, titanium silicon nitride, titanium aluminum nitride, titanium carbide, tungsten, tungsten nitride, tungsten carbide, molybdenum nitride, cobalt, cobalt nitride, ruthenium, palladium, or combinations thereof. In some embodiments, source/drain contacts 180 includes insulation layers (e.g., contact spacers), such as dielectric layers and/or air gaps, between sidewalls of electrically conductive portions thereof (e.g., metal plugs and/or metal liner(s) thereof) and surrounding dielectric materials (e.g., dielectric layer 170).

Silicide layers 185 may be disposed between source/drain contacts 180 and source/drain structures 150 (e.g., semiconductor layers 158 thereof). Silicide layers 185 may include a metal constituent and a semiconductor constituent. The metal constituent may be nickel, platinum, palladium, vanadium, titanium, cobalt, tantalum, ytterbium, zirconium, other suitable metal, or combinations thereof. The semiconductor constituent may be a constituent of source/drain structures 150, such as silicon, germanium, other semiconductor, or combinations thereof. In some embodiments, silicide layers 185 include titanium and silicon, and silicide layers may be referred to as a titanium silicide layers. In some embodiments, an electrical conductivity of silicide layers 185 is greater than an electrical conductivity of semiconductor layers 158 and less than an electrical conductivity of source/drain contacts 180.

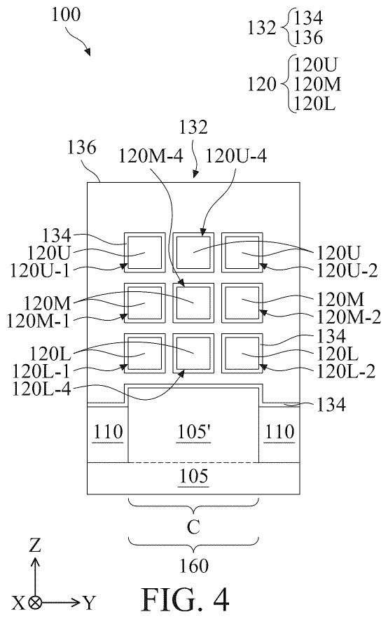

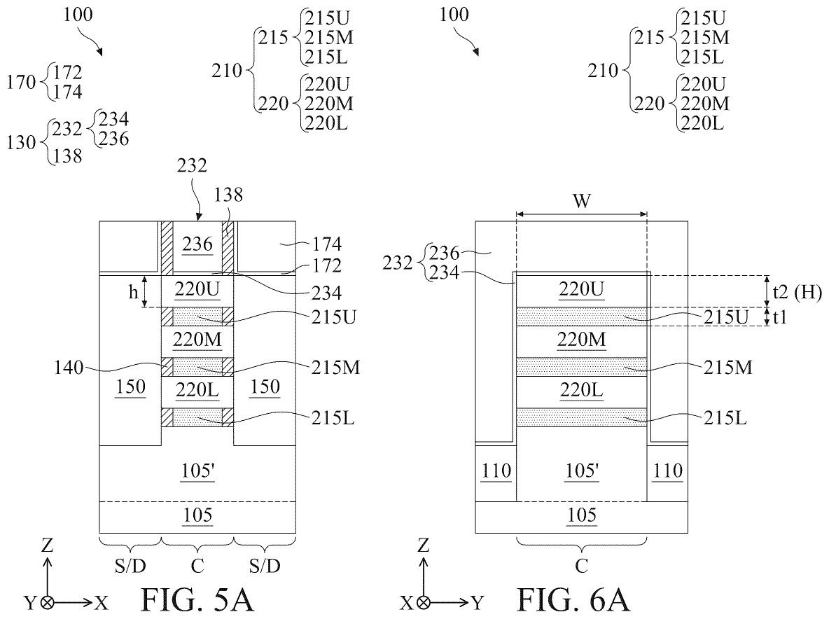

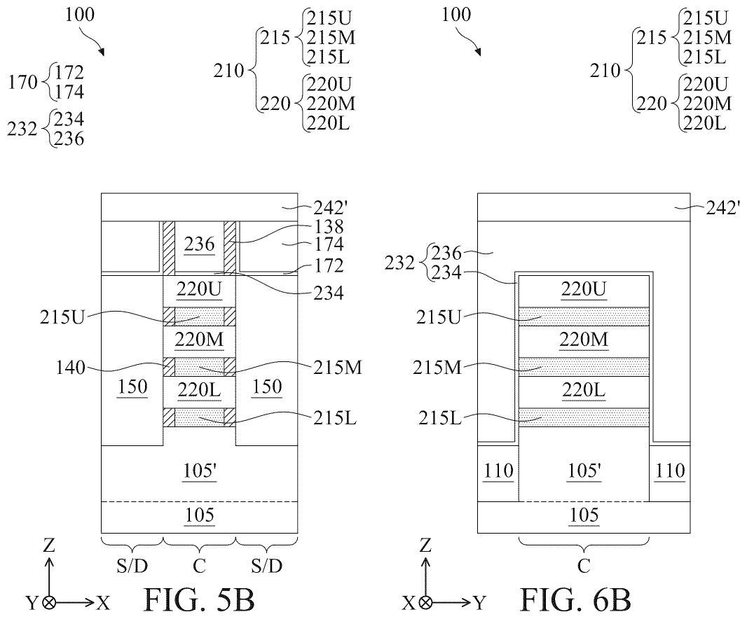

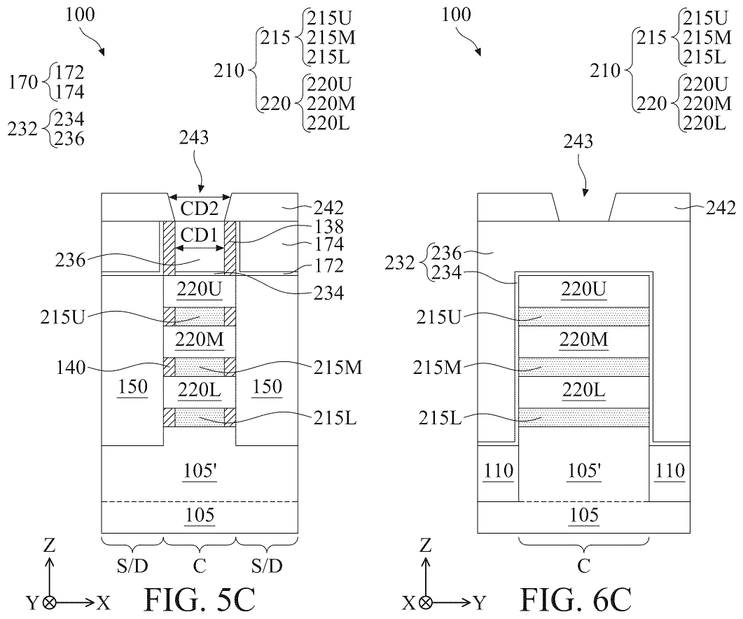

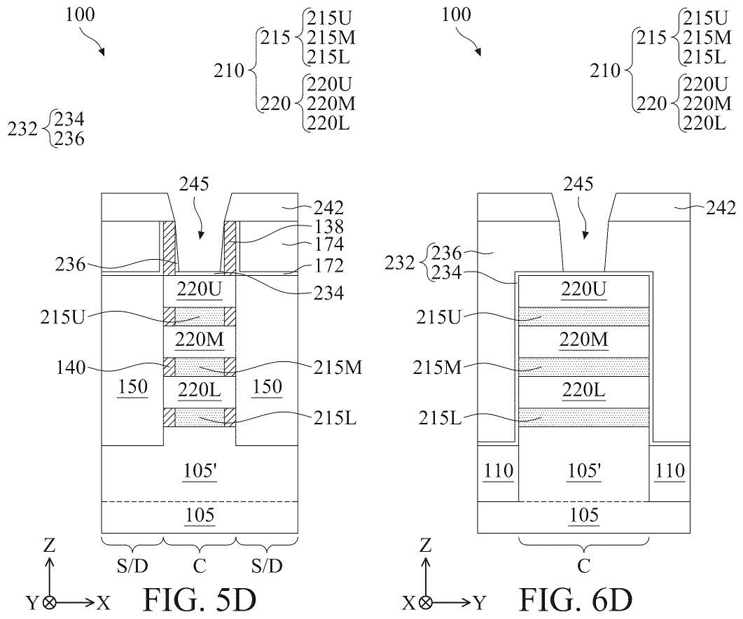

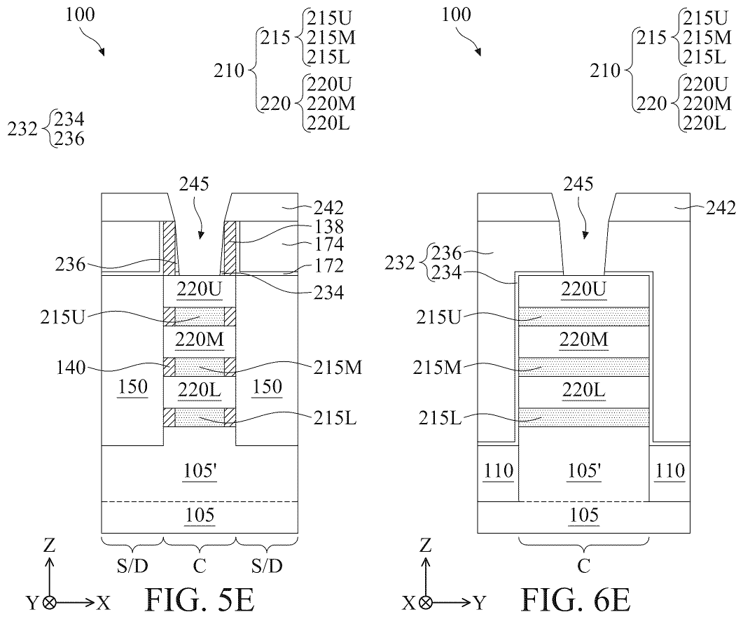

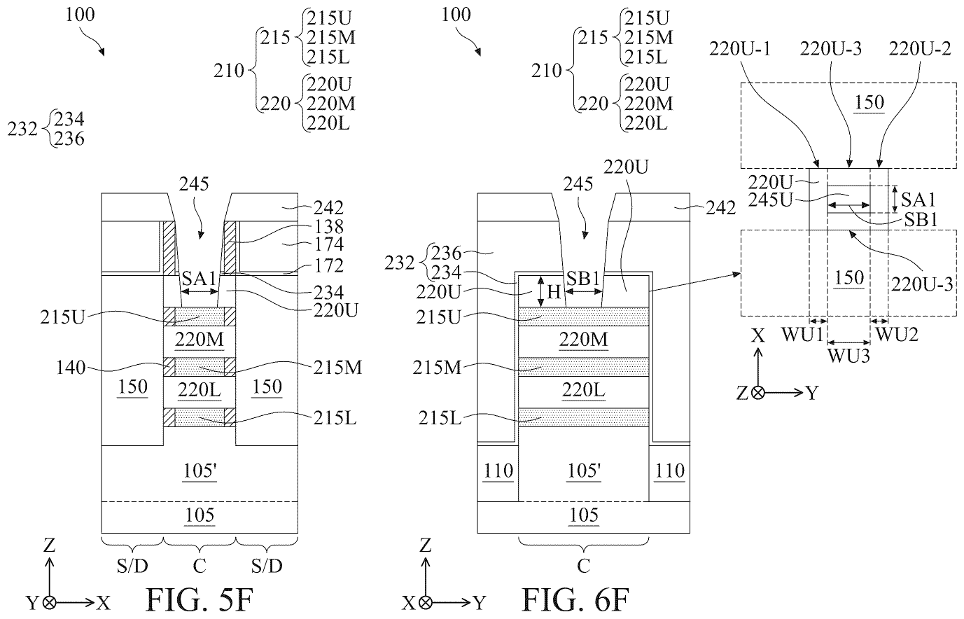

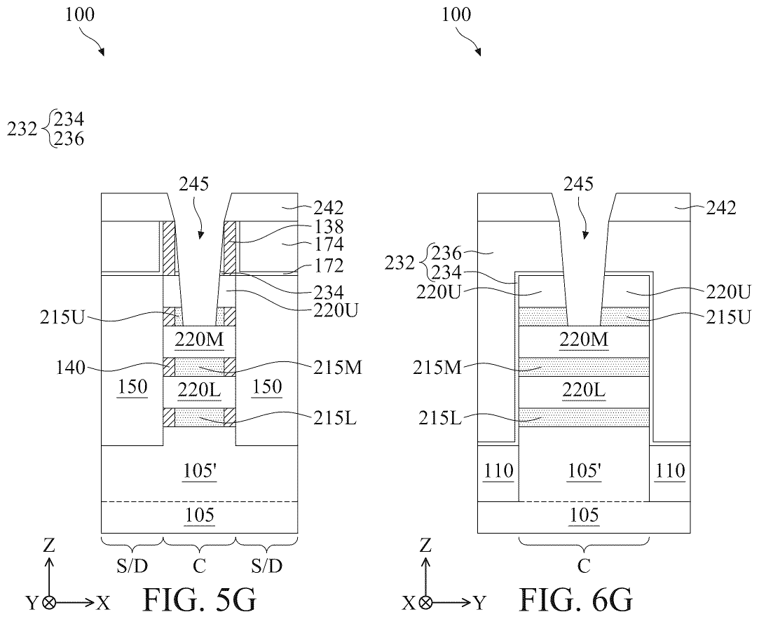

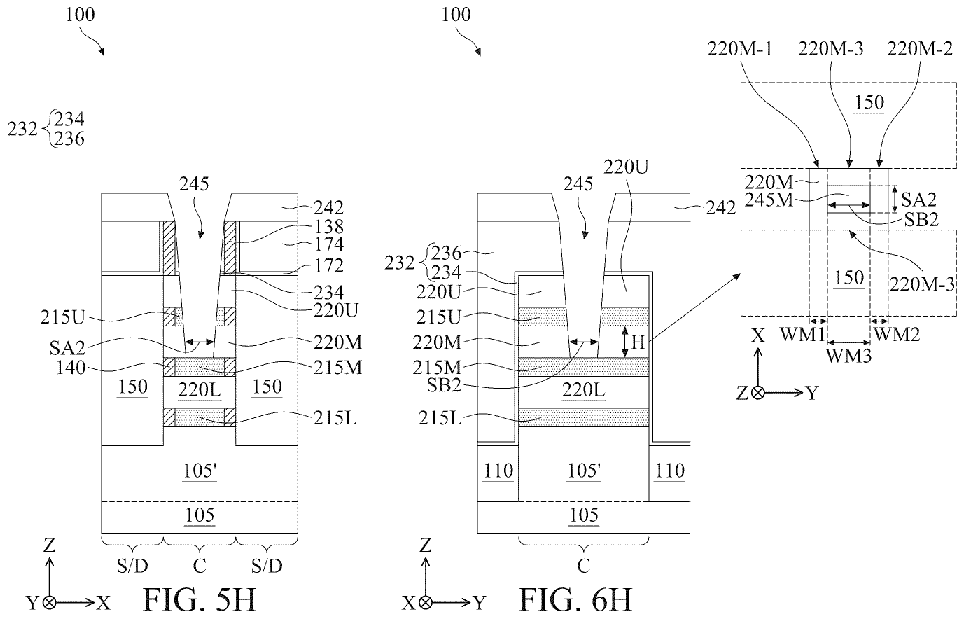

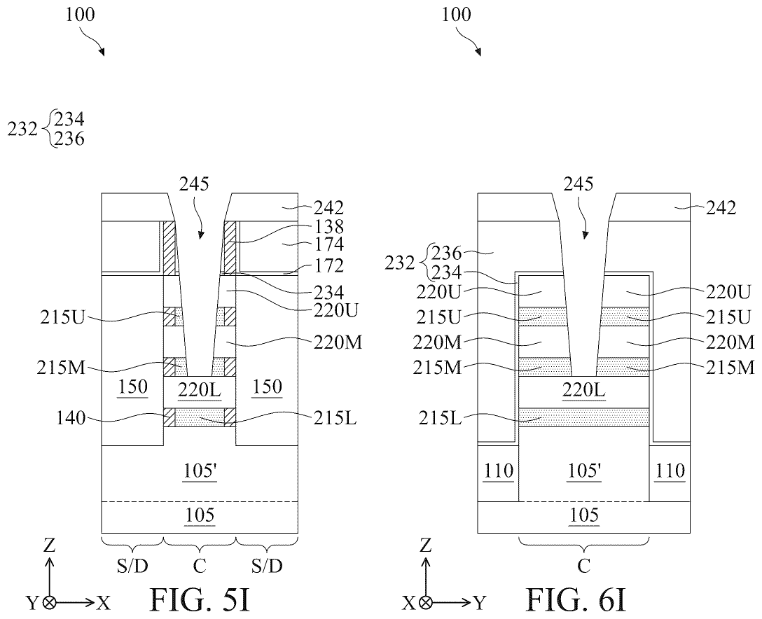

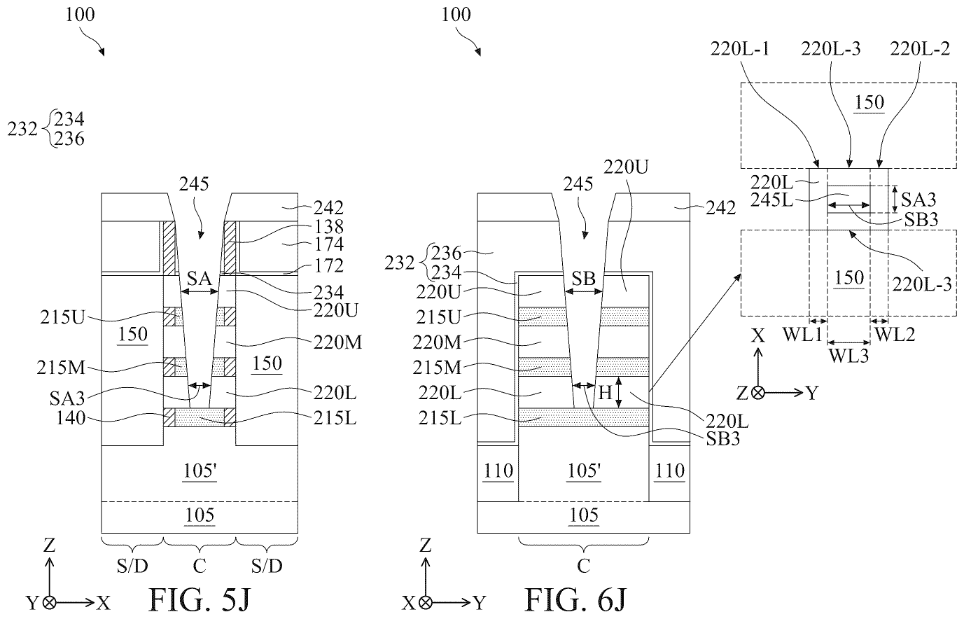

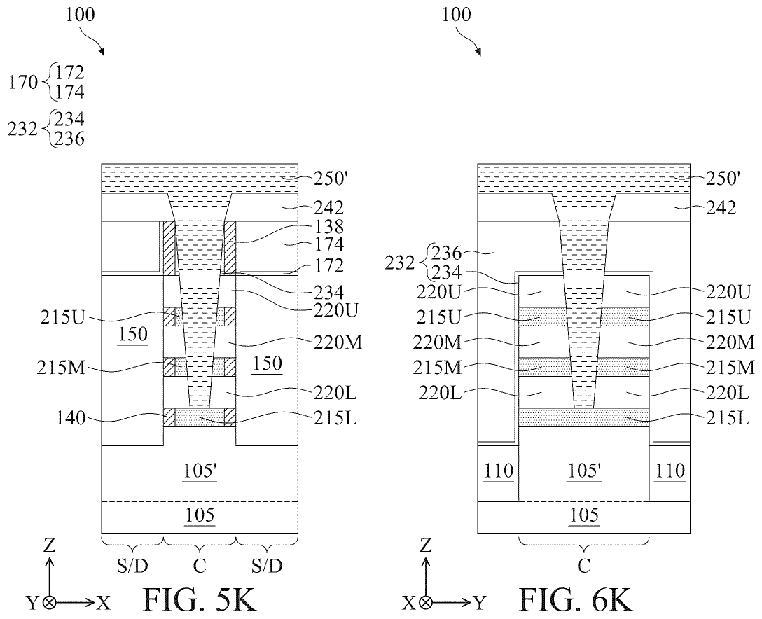

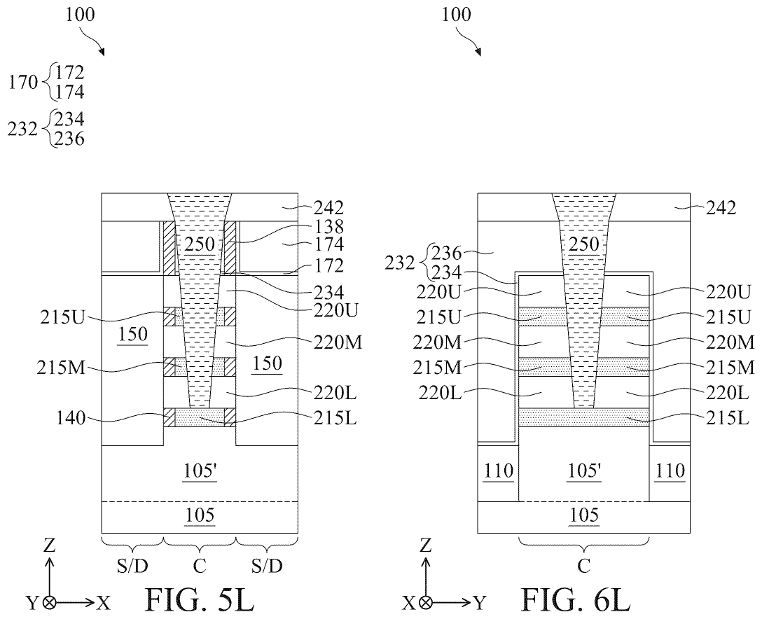

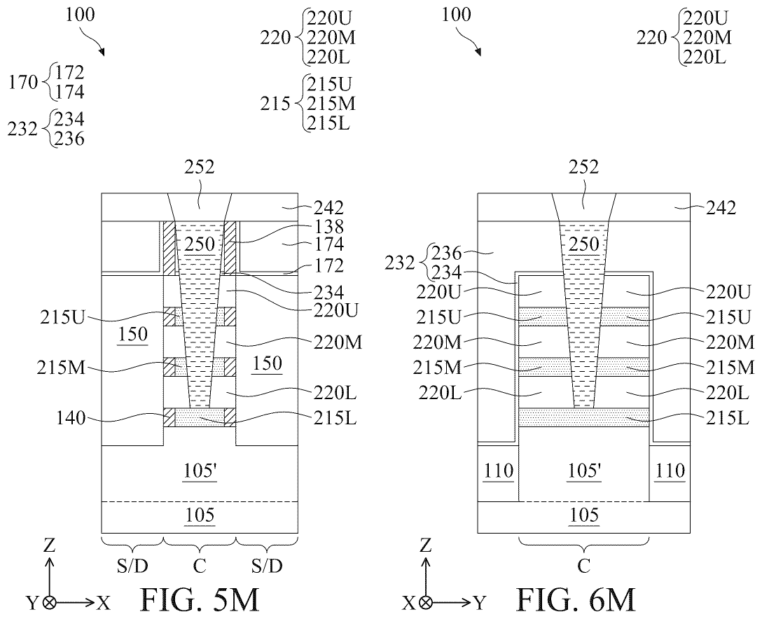

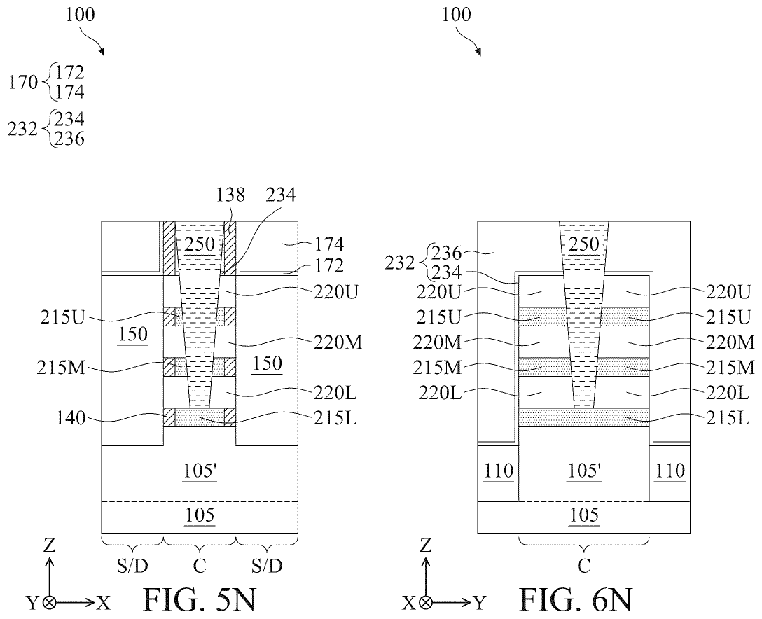

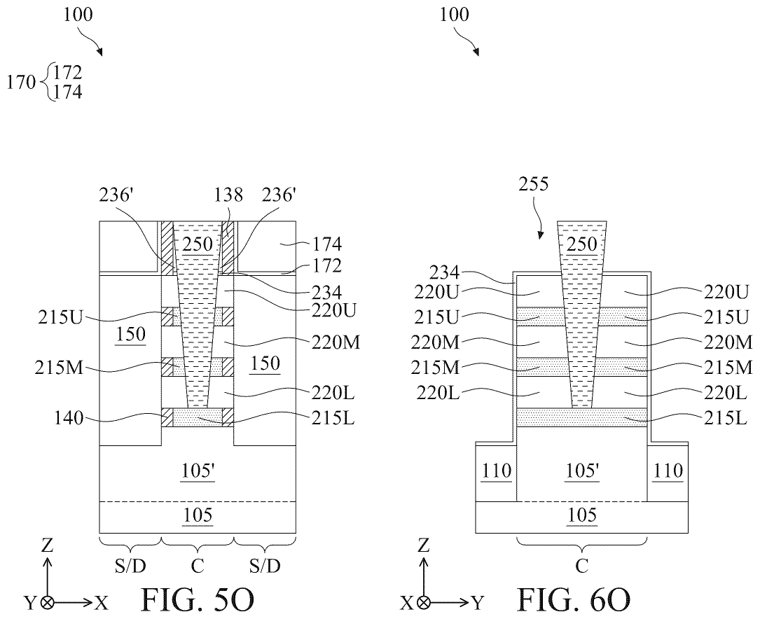

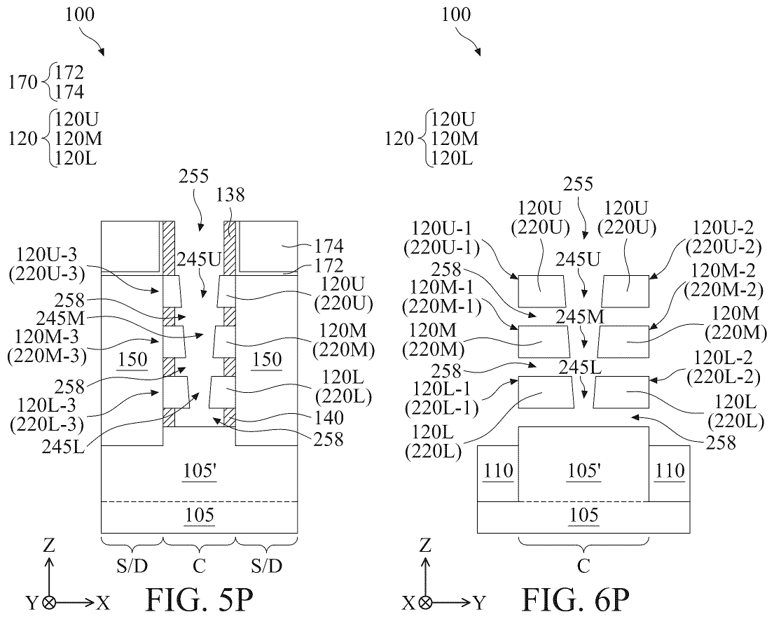

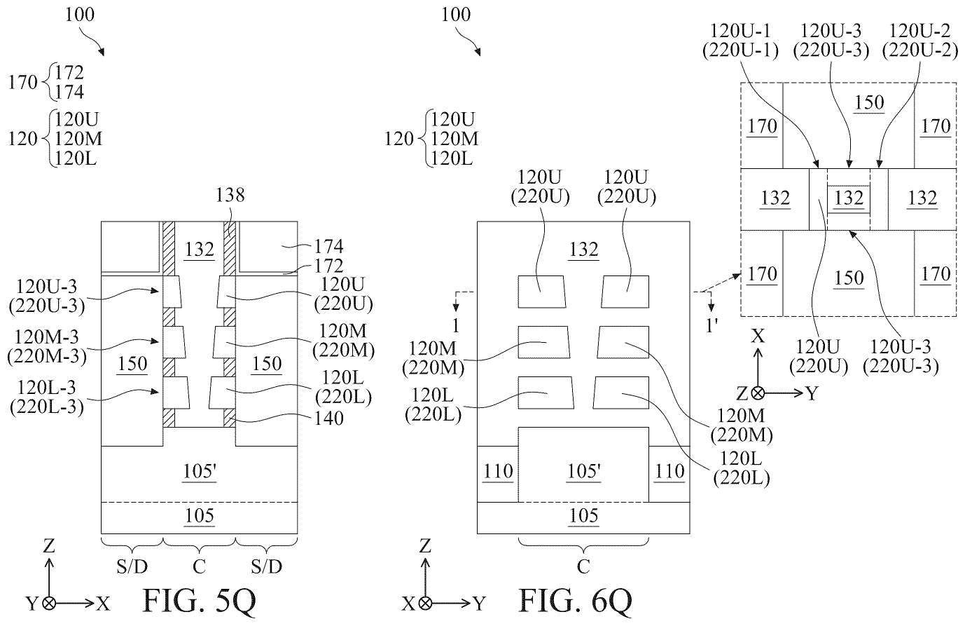

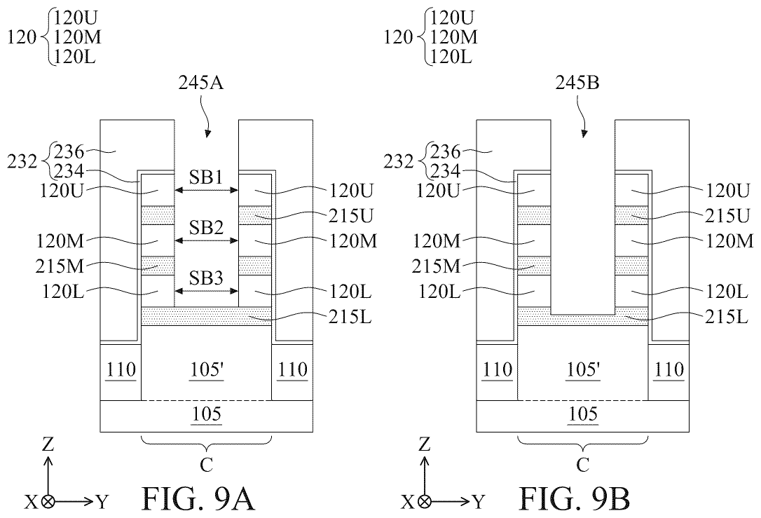

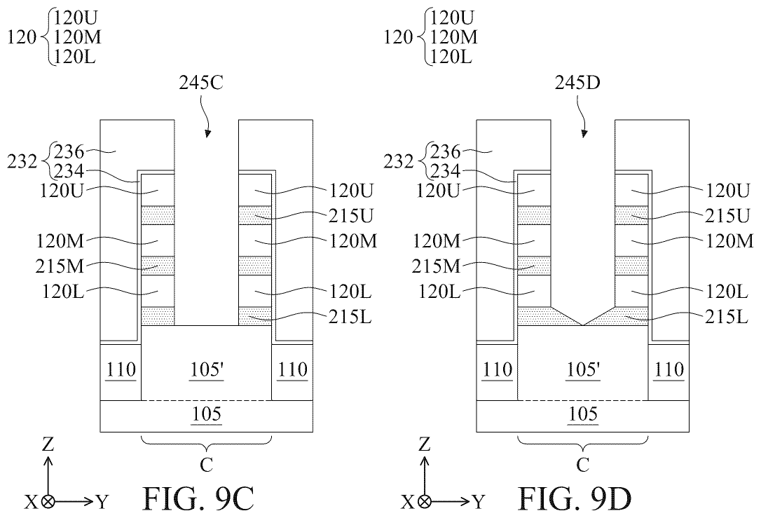

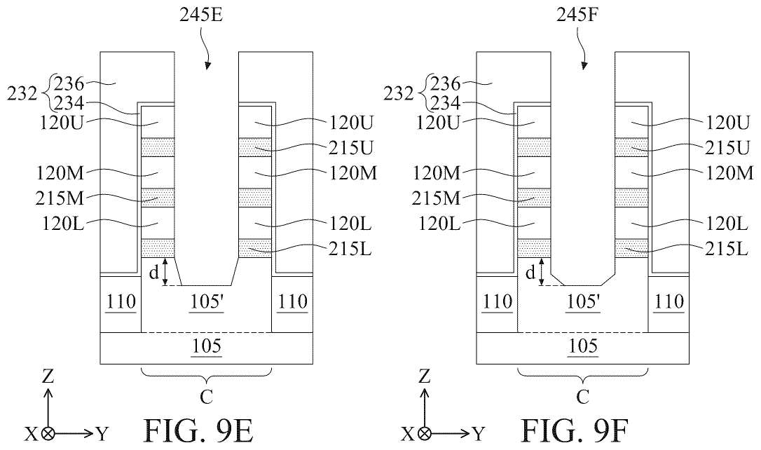

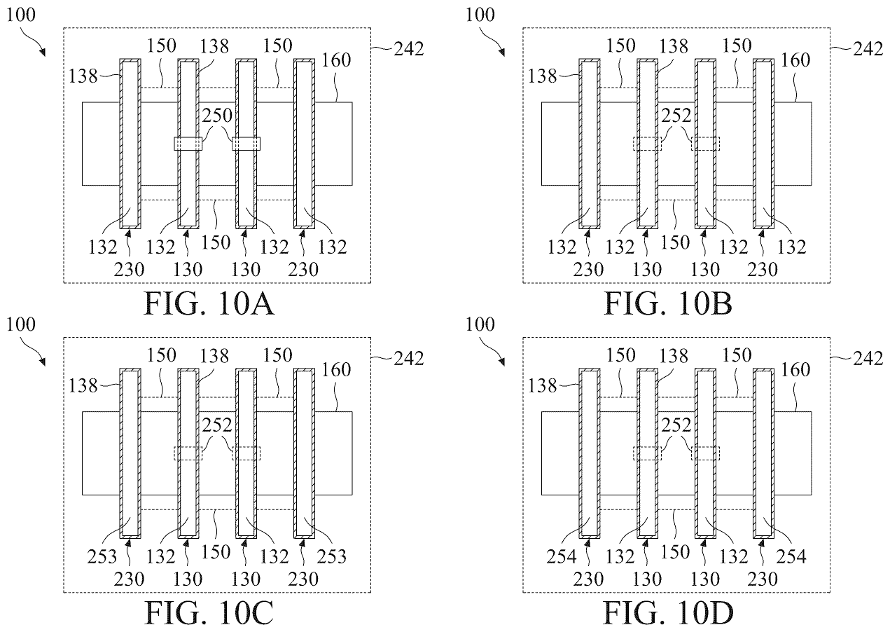

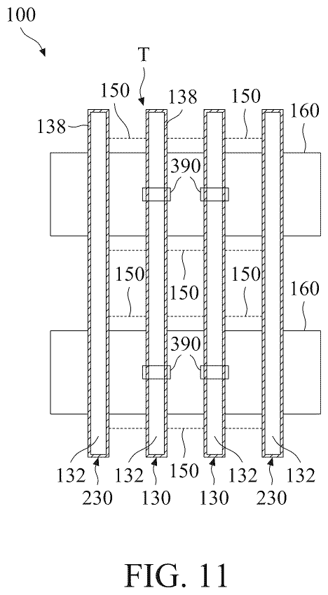

The present disclosure proposes segmenting and/or cutting channels (e.g., semiconductor layers 120) of device 100 before and/or while forming a gate of device 100 (e.g., gate stack 132). FIGS. 5A-5Q are diagrammatic cross-sectional views of device 100, in portion or entirety, along line E-E of FIG. 1A at various stages of a fabrication process, which may implement channel segmentation before forming a gate thereof (e.g., gate stack 132), according to various aspects of the present disclosure. FIGS. 6A-6Q correspond with the various fabrication stages of FIGS. 5A-5Q, respectively, and FIGS. 6A-6Q are diagrammatic cross-sectional views of device 100, in portion or entirety, along line D-D of FIG. 1A according to various aspects of the present disclosure. FIGS. 9A-9F are diagrammatic cross-sectional views of a device, such as device 100, in portion or entirety, at a channel cut stage of a fabrication process, such as that of FIGS. 5A-5Q and FIGS. 6A-6Q, according to various aspects of the present disclosure. FIGS. 10A-10D are diagrammatic top views of a device, such as device 100, in portion or entirety, at a device isolation stage of a fabrication process, such as that of FIGS. 5A-5Q and FIGS. 6A-6Q, according to various aspects of the present disclosure. FIGS. 5A-5Q, FIGS. 6A-6Q, FIGS. 9A-9F, and FIGS. 10A-10D are discussed concurrently herein for ease of description and understanding. FIGS. 5A-5Q, FIGS. 6A-6Q, FIGS. 9A-9F, and FIGS. 10A-10D have been simplified for the sake of clarity to better understand the inventive concepts of the present disclosure. Additional features may be added in device 100 and/or the fabrication process thereof, and some of the features described below may be replaced, modified, or eliminated in other embodiments of device 100 and/or the fabrication process thereof.

Referring to FIG. 5A and FIG. 6A, device 100 may be at an intermediate stage of processing. For example, device 100 includes substrate 105, isolation structures 110, a multilayer stack 210 (including, e.g., protrusion 105′, sacrificial layers 215, and semiconductor layers 220), gate structure 130, inner spacers 140, source/drain structures 150, and dielectric layer 170 (e.g., CESL 172 and ILD layer 174). At the intermediate stage of fabrication, gate structure 130 may include a dummy gate stack 232 and gate spacers 138. Dummy gate stack 232 may include a dummy gate dielectric 234, a dummy gate bulk 236, and a hard mask.

Along an active region lengthwise direction (FIG. 5A), multilayer stack 210 is disposed between source/drain structures 150, inner spacers 140 are disposed between sacrificial layers 215 and source/drain structures 150, and sacrificial layers 220 extend from a first one of source/drain structures 150 to a second one of source/drain structures 150. Sacrificial layers 215 and semiconductor layers 220 are stacked vertically (e.g., along the z-direction) in an interleaving and/or alternating configuration from a top of substrate 105. A composition of sacrificial layers 215 is different than a composition of semiconductor layers 220 to achieve etch selectivity (i.e., provide different etch rates to a given etchant). For example, sacrificial layers 215 and semiconductor layers 220 include different materials, constituent atomic percentages, constituent weight percentages, other characteristics, or combinations thereof to achieve etch selectivity. In some embodiments, sacrificial layers 215 include silicon germanium, and semiconductor layers 220 include silicon. In some embodiments, sacrificial layers 215 and semiconductor layers 220 include the same material but with different constituent atomic percentages, such as silicon germanium with different germanium atomic percentages and/or silicon atomic percentages. In some embodiments, such as the depicted embodiment, sacrificial layers 215 are dielectric layers (e.g., oxide layers) and semiconductor layers 220 are silicon layers or silicon germanium layers. Sacrificial layers 215 and semiconductor layers 220 may include any combination of materials that provides desired etching selectivity, desired oxidation rate differences, desired performance characteristics, or combinations thereof (e.g., materials that maximize current flow), including any of the materials disclosed herein.

In the depicted embodiment, multilayer stack 210 includes three sacrificial layers 215 (e.g., lower sacrificial layer 215L, middle sacrificial layer 215M, and upper sacrificial layer 215U) and three semiconductor layers 220 (e.g., lower semiconductor layer 220L, middle semiconductor layer 220M, and upper semiconductor layer 220U). Multilayer stack 210 thus includes three sacrificial/semiconductor layer pairs over substrate 105, each of which has a respective sacrificial layer 215 and a respective semiconductor layer 220. After processing of multilayer stack 210, this configuration may provide transistor T with three channels. In some embodiments, multilayer stack 210 includes more or less semiconductor layers 220 depending, for example, on a number of channels desired for transistor T. For example, multilayer stack 210 may include two to six sacrificial/semiconductor layer pairs, each of which may include a respective sacrificial layer 215 and a respective semiconductor layer 220.

Sacrificial layers 215 have a thickness t1, and semiconductor layers 220 have a thickness t2, which may be greater than, less than, or the same as thickness t1. In some embodiments, sacrificial layers 215 and semiconductor layers 220 have the same width, such as a width W, along a gate lengthwise direction and/or an active region widthwise direction (see, e.g., FIG. 6A), and a length of sacrificial layers 215 may be less than a length of semiconductor layers 220 along the active region lengthwise direction (see, e.g., FIG. 5A). Thickness t1, thickness t2, width W, and lengths may be chosen based on fabrication and/or device performance considerations. In some embodiments, thickness t2 is configured to provide a desired thickness and/or a desired height of channels of transistor T (i.e., thickness t2 corresponds with a height H of channels of transistor T), and thickness t1 is configured to provide a desired spacing/distance between adjacent channels of transistor T (e.g., between semiconductor layers 220).

Along the active region lengthwise direction (FIG. 5A), dummy gate stack 232 is disposed on top of multilayer stack 210 and between source/drain structures 150. Along a gate lengthwise direction (FIG. 6A), dummy gate stack 232 extends along the y-direction, having a length along the y-direction, a width along the x-direction, and a height along the z-direction. Dummy gate stack 232 may wrap multilayer stack 210 (e.g., be disposed over the top and sidewalls thereof), and dummy gate stack 232 may be disposed over tops of isolation structures 110. Dummy gate dielectric 234 includes a dielectric material, such as silicon oxide and/or other suitable dielectric material. Where sacrificial layers 215 are formed of a dielectric material, such as in the depicted embodiment, dummy gate dielectric 234 may be formed of the same or a different dielectric material. For example, dummy gate dielectric 234 and sacrificial layers 215 may be silicon oxide layers having the same composition or different compositions. Dummy gate bulk 236 includes a suitable placeholder/sacrificial material, such as polysilicon. In some embodiments, dummy gate stack 232 may further include a hard mask, which may be configured to protect dummy gate dielectric 234 and/or dummy gate bulk 236 during processing. For example, the hard mask may include a material that is resistant to an etching process, such as etching associated with forming source/drain recesses and/or etching associated with forming source/drain contact openings, to protect dummy gate dielectric 234 and/or the dummy gate bulk 236 therefrom. In some embodiments, the hard mask has a multilayer structure.

Referring to FIGS. 5B-5J and FIGS. 6B-6J, semiconductor layers 220 are segmented and/or cut through before a gate replacement process (e.g., before dummy gate stack 232 is removed and replaced with gate stack 132) and/or before a channel release process (e.g., selectively removing sacrificial layers 215 to suspend semiconductor layers 220 over substrate 105). Referring to FIG. 5B, FIG. 6B, FIG. 5C, and FIG. 6C, segmenting of semiconductor layers 220 may include forming a patterned hard mask 242 over device 100 (e.g., on dielectric layer 170 and gate structure 130, both of which form a top of device 100 at this stage of fabrication). Patterned hard mask 242 includes an opening therein, such as an opening 243, that is disposed over and overlaps multilayer stack 210. In the depicted embodiment, opening 243 exposes a portion of dummy gate stack 232 that covers multilayer stack 210. A width of opening 243 is greater than a width of dummy gate stack 232 (and/or gate stack 132). For example, dummy gate stack 232 has a critical dimension CD1, opening 243 has a critical dimension CD2, and critical dimension CD2 is greater than critical dimension CD1. In some embodiments, critical dimension CD2 is about 2 nm to about 10 nm greater than critical dimension CD1. Critical dimension CD1 corresponds with “a gate length” (L_{g}) of transistor T along the active region lengthwise direction (e.g., along the x-direction), which may correspond with a distance (or length) that current may travel between source/drain structures 150, and critical dimension CD2 corresponds with a width of a channel cut along the active region lengthwise direction (e.g., along the x-direction). In some embodiments, critical dimension CD1 is less than about 12 nm (e.g., CD1≤12 nm). In some embodiments, such as depicted, opening 243 has tapered sidewalls, such that critical dimension CD2 decreases (or increases) from top to bottom of opening 243. In some embodiments, critical dimension CD2 is greater than critical dimension CD1 (e.g., by about 2 nm to about 10 nm) at least at a top of opening 243.

Patterned hard mask 242 may be formed by depositing a mask layer 242′ over device 100 (FIG. 5B and FIG. 6B) and patterning mask layer 242′ (FIG. 5C and FIG. 6C) to include one or more openings therein, such as opening 243. The patterning may include etching mask layer 242′ using a patterned resist layer as an etch mask. The patterned resist layer may be formed by a lithography process, which may include resist coating (e.g., spin-on coating), soft baking, mask aligning, exposure, post-exposure baking, developing the resist, rinsing, drying (e.g., hard baking), other suitable process, or combinations thereof. Mask layer 242′, and thus patterned hard mask 242, include a material that is negligibly (or minimally) etched/removed during selective etching/removal of sacrificial layers 215, semiconductor layers 220, and dummy gate stack 232 exposed by opening 243. In some embodiments, mask layer 242′ is a silicon nitride layer, and patterned hard mask 242 is a silicon nitride mask. In some embodiments, mask layer 242′ and/or patterned hard mask 242 include silicon and nitrogen, carbon, oxygen, or combinations thereof. In some embodiments, mask layer 242′ and/or patterned hard mask 242 include metal and nitrogen, carbon, oxygen, or combinations thereof. In some embodiments, mask layer 242′ and/or patterned hard mask 242 has a multilayer structure.

Referring to FIGS. 5D-5J and FIGS. 6D-6J, segmenting of semiconductor layers 220 may include forming at least one channel cut 245 in multilayer stack 210 that extends through at least one of semiconductor layers 220. In some embodiments, such as depicted, channel cut 245 extends partially through multilayer stack 210. For example, channel cut 245 extends through dummy gate stack 232 (e.g., dummy gate bulk 236 and dummy gate dielectric 234), semiconductor layer 220U, sacrificial layer 215U, semiconductor layer 220M, sacrificial layer 215M, and semiconductor layer 220L. Channel cut 245 thus extends through all semiconductor layers 220, but stops at and exposes sacrificial layer 215L (i.e., bottommost sacrificial layer 215). In some embodiments, such as depicted, channel cut 245 has tapered sidewalls, such that a width of channel cut 245 decreases from top to bottom thereof. In such embodiments, as described further herein, spacing SA (e.g., along the x-direction) and spacing SB (e.g., along the y-direction) between segments of multilayer stack 210 may decrease from top to bottom thereof. For example, along the gate widthwise direction, a spacing SA1 between segments of semiconductor layer 220U is greater than a spacing SA2 between segments of semiconductor layer 220M, which is greater than a spacing SA3 between segments of semiconductor layer 220L. Further, along the gate lengthwise direction, a spacing SB1 between segments of semiconductor layer 220U is greater than a spacing SB2 between segments of semiconductor layer 220M, which is greater than a spacing SB3 between segments of semiconductor layer 220L. Spacing between segments of sacrificial layers 215 may similarly decrease from top to bottom of multilayer stack 210. In some embodiments, a width of channel cut 245 may increase, instead of decrease, from top to bottom thereof, such that spacing SA and/or spacing SB may increase from top to bottom of multilayer stack 210. In some embodiments, channel cut 245 has substantially straight sidewalls (e.g., extending along the z-direction), and a width of channel cut 245 is substantially uniform from top to bottom thereof, such that spacing SA and/or spacing SB is substantially the same from top to bottom of multilayer stack 210.

An etching process may use patterned hard mask 242 to form channel cut 245, and patterned hard mask 242 may protect dielectric layer 170 (e.g., ILD layer 174 and/or CESL 172 thereof) and gate spacers 138 during the etching process. The etching process may include and/or be a dry etch, a wet etch, other suitable etching process, or combinations thereof. In some embodiments, the etching process is a multistep etch. For example, the etching process may alternate etchants and/or tune other etch parameters (e.g., etch time, etch temperature, etch pressure, flow rate of etchants, etc.) to separately and alternately remove dummy gate bulk 236 (FIG. 5D and FIG. 6D), dummy gate dielectric 234 (FIG. 5E and FIG. 6E), semiconductor layer 220U (FIG. 5F and FIG. 6F), sacrificial layer 215U (FIG. 5G and FIG. 6G), semiconductor layer 220M (FIG. 5H and FIG. 6H), sacrificial layer 215M (FIG. 5I and FIG. 6I), and semiconductor layer 220L (FIG. 5J and FIG. 6J). In some embodiments, the etching process includes selectively removing dummy gate bulk 236 with respect to dummy gate dielectric 234 (FIG. 5D and FIG. 6D) (e.g., a first etch step); selectively removing dummy gate dielectric 234 with respect to dummy gate bulk 236 and semiconductor layer 220U (FIG. 5E and FIG. 6E) (e.g., a second etch step); selectively removing semiconductor layer 220U with respect to dummy gate bulk 236, dummy gate dielectric 234, and sacrificial layer 215U (FIG. 5F and FIG. 6F) (e.g., a third etch step); selectively removing sacrificial layer 215U with respect to dummy gate bulk 236, semiconductor layer 220U, and semiconductor layer 220M (FIG. 5G and FIG. 6G) (e.g., a fourth etch step); selectively removing semiconductor layer 220M with respect to dummy gate bulk 236, dummy gate dielectric 234, sacrificial layer 215U, and sacrificial layer 215M (FIG. 5H and FIG. 6H) (e.g., a fifth etch step); selectively removing sacrificial layer 215M with respect to dummy gate bulk 236, semiconductor layer 220U, semiconductor layer 220M, and semiconductor layer 220L (FIG. 5I and FIG. 6I) (e.g., a sixth etch step); and selectively removing semiconductor layer 220L with respect to dummy gate bulk 236, dummy gate dielectric 234, sacrificial layer 215U, sacrificial layer 215M, and sacrificial layer 215L (FIG. 5J and FIG. 6J) (e.g., a seventh etch step). In some embodiments, dummy gate bulk 236 is formed of polysilicon (Poly), dummy gate dielectric 234 and sacrificial layers 215 are formed of oxide (Ox) (having the same composition or different compositions), semiconductor layers 220 are formed of silicon (Si), and the etching process may be a Poly/Ox/Si/Ox/Si/Ox/Si etch. The etching process may use different etchants to separately remove polysilicon, oxide, and silicon. For example, the etching process may implement a first etchant to selectively remove polysilicon without (or negligibly) removing oxide and silicon, a second etchant to selectively remove oxide without (or negligibly) removing polysilicon and silicon, and a third etchant to selectively remove silicon without (or negligibly) removing polysilicon and oxide. In some embodiments, multiple etching steps of the etching process are performed in a same process chamber. For example, when the etching process is a Poly/Ox/Si/Ox/Si/Ox/Si etch, device 100 may be exposed to the first etchant, the second etchant, and the third etchant in a same process chamber. In some embodiments, after each etch step, a purge process may be performed to remove a given etchant of a respective etch step and any byproducts before performing a next etch step in the same process chamber. In some embodiments, the etching process is an anisotropic dry etch.

In the depicted embodiment, the etching process forms channel cut 245 without (or negligibly) etching/removing patterned hard mask 242. In some embodiments, the etching process may slowly remove patterned hard mask 242 during etching/removal of one or more of dummy gate bulk 236, dummy gate dielectric 234, semiconductor layers 220, sacrificial layers 215, or combinations thereof. In such embodiments, the etching process may reduce a thickness of patterned hard mask 242. In other words, a thickness of patterned hard mask 242 after the etching process may be less than an initial thickness of patterned hard mask 242.

After channel cut 245, semiconductor layers 220 have ring-shaped profiles, instead of sheet-shaped profiles. For example, referring to FIG. 5F and FIG. 6F, semiconductor layer 220U has an opening 245U (also referred to as a hole) therein formed by channel cut 245, and channel cut 245 provides semiconductor layer 220U with a semiconductor segment 220U-1 extending lengthwise along the active region lengthwise direction (e.g., the x-direction), a semiconductor segment 220U-2 extending lengthwise along the active region lengthwise direction (e.g., the x-direction), and semiconductor segments 220U-3 extending lengthwise along the gate lengthwise direction (e.g., the y-direction) from semiconductor segment 220U-1 to semiconductor segment 220U-2. Semiconductor segments 220U-3 are separated by spacing SA1 (e.g., along the x-direction), and semiconductor segments 220U-3 connect and/or stitch together semiconductor segment 220U-1 and semiconductor segment 220U-2. Semiconductor segment 220U-1 and semiconductor segment 220U-2 are separated by spacing SB1 (e.g., along the y-direction). In some embodiments, since channel cut 245 may have tapered sidewalls, spacing SA1 and/or spacing SB1 may decrease (or increase) from top to bottom of semiconductor layer 220U. Semiconductor segment 220U-1 and semiconductor segment 220U-2 extend between source/drain structures 150, and semiconductor segment 220U-1 and semiconductor segment 220U-2 may provide channels of transistor T, as described herein.

Semiconductor segment 220U-1 and semiconductor segment 220U-2 have widths that are less than a width of semiconductor layer 220U before channel cut 245. For example, semiconductor segment 220U-1 has a width WU1 (e.g., along the y-direction), semiconductor segment 220U-2 has a width WU2 (e.g., along the y-direction), and semiconductor segments 220U-3 have a width WU3 (e.g., along the y-direction). Width WU1, width WU2, and width WU3 are less than width W, and a sum of width WU1, width WU2, and width WU3 is equal to width W (i.e., a width of semiconductor layer 220U having the sheet-shaped profile). Because width WU1 and width WU2 are less than width W, width/height ratios of semiconductor segment 220U-1 and semiconductor segment 220U-2 are less than a width/height ratio of semiconductor layer 220U before channel cut 245. For example, a ratio of width WU1 to height H (i.e., WU1/H) is less than a ratio of width W to height H (i.e., W/H), and a ratio of width WU2 to height H (i.e., WU2/H) is less than W/H. In some embodiments, W/H is greater than or equal to 2 (i.e., W/H>2), WU1/H is less than about 2 and greater than about 0.5 (i.e., 0.5<WU1/H<2), and WU2/H is less than about 2 and greater than about 0.5 (i.e., 0.5<WU2/H<2). In some embodiments, such as depicted, width WU1 and width WU2 are about the same. In some embodiments, width WU1 is less than or greater than width WU2. In some embodiments, since channel cut 245 may have tapered sidewalls, width WU1 and/or width WU2 may increase (or decrease) along height H from top to bottom of semiconductor layer 220U.

Because of their reduced widths and/or reduced width/height ratios, semiconductor segment 220U-1 and semiconductor segment 220U-2 may have cylindrical-shaped profiles or rectangular-shaped profiles, and semiconductor segment 220U-1 and semiconductor segment 220U-2 may be nanowires or nanobars, respectively, of transistor T. Channel cut 245 thus modifies a nanosheet (e.g., semiconductor layer 220U having a sheet-shaped profile) into nanowires and/or nanobars (e.g., semiconductor segment 220U-1 and semiconductor segment 220U-2) that are stitched together (e.g., by semiconductor segments 220U-3). As described further below, such configuration improves gate control and/or reduces SCE. The present disclosure contemplates semiconductor segment 220U-1 and semiconductor segment 220U-2 having any other suitable shaped profile. Further, in some embodiments, semiconductor layers 220 (and their various segments) have nanometer-sized dimensions and may be referred to as “nanostructures.” In some embodiments, semiconductor layers 220 (and their various segments) have sub-nanometer dimensions and/or super-nanometer dimensions.

Semiconductor layer 220M may also have a ring-shaped profile. For example, referring to FIG. 5H and FIG. 6H, semiconductor layer 220M has an opening 245M therein formed by channel cut 245, and channel cut 245 provides semiconductor layer 220M with a semiconductor segment 220M-1, a semiconductor segment 220M-2, and semiconductor segments 220M-3 extending from semiconductor segment 220M-1 to semiconductor segment 220M-2. Semiconductor segments 220M-3 are separated by spacing SA2, and semiconductor segments 220M-3 connect and/or stitch together semiconductor segment 220M-1 and semiconductor segment 220M-2. In some embodiments, since channel cut 245 may have tapered sidewalls, spacing SA2 and/or spacing SB2 may decrease (or increase) from top to bottom of semiconductor layer 220M. Semiconductor segment 220M-1 and semiconductor segment 220M-2 are separated by spacing SB2. Semiconductor segment 220M-1 and semiconductor segment 220M-2 extend between source/drain structures 150, and semiconductor segment 220M-1 and semiconductor segment 220M-2 may provide channels of transistor T.

Semiconductor segment 220M-1 and semiconductor segment 220M-2 have widths that are less than a width of semiconductor layer 220M before channel cut 245. For example, semiconductor segment 220M-1 has a width WM1 (e.g., along the y-direction), semiconductor segment 220M-2 has a width WM2 (e.g., along the y-direction), and semiconductor segments 220M-3 have a width WM3 (e.g., along the y-direction). Width WM1, width WM2, and width WM3 are less than width W, and a sum of width WM1, width WM2, and width WM3 is equal to width W (i.e., a width of semiconductor layer 220M having the sheet-shaped profile). Because width WM1 and width WM2 are less than width W, width/height ratios of semiconductor segment 220M-1 and semiconductor segment 220M-2 are less than a width/height ratio of semiconductor layer 220M before channel cut 245. For example, a ratio of width WM1 to height H (i.e., WM1/H) is less than W/H, and a ratio of width WM2 to height H (i.e., WM2/H) is less than W/H. In some embodiments, W/H is greater than or equal to 2, WM1/H is less than about 2 and greater than about 0.5 (i.e., 0.5<WM1/H<2), and WM2/H is less than about 2 and greater than about 0.5 (i.e., 0.5<WM2/H<2). In some embodiments, width WM1 and width WM2 are about the same. In some embodiments, width WM1 is less than or greater than width WM2. In some embodiments, since channel cut 245 may have tapered sidewalls, width WM1 and/or width WM2 may increase (or decrease) from top to bottom of semiconductor layer 220M.

Semiconductor layer 220L may also have a ring-shaped profile. For example, referring to FIG. 5J and FIG. 6J, semiconductor layer 220L has an opening 245L therein formed by channel cut 245, and channel cut 245 provides semiconductor layer 220L with a semiconductor segment 220L-1, a semiconductor segment 220L-2, and semiconductor segments 220L-3 extending from semiconductor segment 220L-1 to semiconductor segment 220L-2. Semiconductor segments 220L-3 are separated by spacing SA3, and semiconductor segments 220L-3 connect and/or stitch together semiconductor segment 220L-1 and semiconductor segment 220L-2. Semiconductor segment 220L-1 and semiconductor segment 220L-2 are separated by spacing SB3. In some embodiments, since channel cut 245 may have tapered sidewalls, spacing SA3 and/or spacing SB3 may decrease (or increase) from top to bottom of semiconductor layer 220L. Semiconductor segment 220L-1 and semiconductor segment 220L-2 extend between source/drain structures 150, and semiconductor segment 220L-1 and semiconductor segment 220L-2 may provide channels of transistor T.

Semiconductor segment 220L-1 and semiconductor segment 220L-2 have widths that are less than a width of semiconductor layer 220L before channel cut 245. For example, semiconductor segment 220L-1 has a width WL1 (e.g., along the y-direction), semiconductor segment 220L-2 has a width WL2 (e.g., along the y-direction), and semiconductor segments 220L-3 have a width WL3 (e.g., along the y-direction). Width WL1, width WL2, and width WL3 are less than width W, and a sum of width WL1, width WL2, and width WL3 is equal to width W (i.e., a width of semiconductor layer 220L having the sheet-shaped profile). Because width WL1 and width WL2 are less than width W, width/height ratios of semiconductor segment 220L-1 and semiconductor segment 220L-2 are less than a width/height ratio of semiconductor layer 220L before channel cut 245. For example, a ratio of width WL1 to height H (i.e., WL1/H) is less than W/H, and a ratio of width WL2 to height H (i.e., WL2/H) is less than W/H. In some embodiments, W/H is greater than or equal to 2, WL1/H is less than about 2 and greater than about 0.5 (i.e., 0.5<WL1/H<2), and WL2/H is less than about 2 and greater than about 0.5 (i.e., 0.5<WL2/H<2). In some embodiments, width WL1 and width WL2 are about the same. In some embodiments, width WL1 is less than or greater than width WL2. In some embodiments, since channel cut 245 may have tapered sidewalls, width WL1 and/or width WL2 may increase (or decrease) from top to bottom of semiconductor layer 220L.

Because of their reduced widths and/or reduced width/height ratios, semiconductor segment 220M-1, semiconductor segment 220M-2, semiconductor segment 220L-1, and semiconductor segment 220L-2 may have cylindrical-shaped profiles or rectangular-shaped profiles, and semiconductor segment 220M-1, semiconductor segment 220M-2, semiconductor segment 220L-1, and semiconductor segment 220L-2 may be nanowires or nanobars, respectively, of transistor T. Channel cut 245 thus modifies nanosheets (e.g., semiconductor layer 220M and semiconductor layer 220L having sheet-shaped profiles) into nanowires and/or nanobars (e.g., semiconductor segment 220M-1, semiconductor segment 220M-2, semiconductor segment 220L-1, and semiconductor segment 220L-2) that are stitched together (e.g., by semiconductor segments 220M-3 or semiconductor segments 220L-3). As described further below, such configuration improves gate control and/or reduces SCE. The present disclosure contemplates semiconductor segments having any other suitable shaped profile.

Referring to FIGS. 9A-9E, the present disclosure contemplates tuning and/or configuring the etching process to provide channel cuts through multilayer stack 210 with various configurations and/or profiles. In some embodiments, such as depicted in FIG. 9A, a channel cut 245A having substantially straight sidewalls (e.g., extending along the z-direction), instead of tapered sidewalls, may be formed in and extend through dummy gate stack 232 and multilayer stack 210. In such embodiments, a width of channel cut 245A is substantially uniform from top to bottom thereof, such that spacing SA and spacing SB are substantially the same from top to bottom of multilayer stack 210. For example, spacing SB1 may be about spacing SB2, and spacing SB2 may be about spacing SB3 (i.e., SB1≈SB2≈SB3). Further, in such embodiments, width WU1, width WU2, width WM1, width WM2, width WL1, width WL2, or combinations thereof may be substantially the same along their heights H.

In some embodiments, such as depicted in FIGS. 9B-9D, a channel cut may extend into bottommost sacrificial layer 215. For example, in FIG. 9B, a channel cut 245B may extend partially into sacrificial layer 215L, such that a portion of sacrificial layer 215L remains between a bottom of channel cut 245B and protrusion 105′. In another example, in FIG. 9C and FIG. 9D, a channel cut 245C and a channel cut 245D may extend completely through sacrificial layer 215L, such that channel cut 245C and channel cut 245D expose protrusion 105′. In some embodiments, such as depicted in FIG. 9E and FIG. 9F, a channel cut may extend into protrusion 105′ and/or substrate 105. For example, a channel cut 245E and a channel cut 245F may extend completely through sacrificial layer 215L and a distance d into protrusion 105′ and/or substrate 105, such that channel cut 245C and channel cut 245D may expose protrusion 105′. In some embodiments, distance d is less than about 20 nm (e.g., 0 nm≤d≤20 nm).

In some embodiments, a channel cut may be configured with a substantially flat bottom, such as channel cut 245A (e.g., having a bottom formed by sacrificial layer 215L), channel cut 245B (e.g., having a bottom formed by sacrificial layer 215L), and channel cut 245C (e.g., having a bottom formed by protrusion 105′). In some embodiments, a channel cut may be configured with a rounded bottom, which may or may not have a defined tip, such as channel cut 245D (e.g., having a bottom formed by sacrificial layer 215L and protrusion 105′). In some embodiments, a channel cut may be configured with a trapezoidal-shaped bottom, such as channel cut 245E (e.g., having a bottom formed by protrusion 105′), a pentagonal-shaped bottom, such as channel cut 245F (e.g., having a bottom formed by protrusion 105′), or other suitably shaped bottom. It is noted that, though the embodiments of FIGS. 9A-9F depict the channel cuts having straight sidewalls, the present disclosure contemplates embodiments of FIGS. 9A-9F where the channel cuts have tapered sidewalls, such as channel cut 245.

Referring to FIG. 5K, FIG. 6K, FIG. 5L, and FIG. 6L, fabrication of device 100 may include forming a sacrificial plug 250 in channel cut 245. Sacrificial plug 250 is disposed in dummy gate stack 232 and multilayer stack 210, and sacrificial plug 250 extends through semiconductor layers 220. Forming sacrificial plug 250 may include depositing a sacrificial material 250′ over device 100 that fills channel cut 245 (FIG. 5K and FIG. 6K) and performing a planarization process (e.g., a chemical mechanical polish (CMP)) to remove sacrificial material 250′ formed over dielectric layer 170 and/or gate spacers 138 (FIG. 5L and FIG. 6L), such as portions of sacrificial material 250′ that do not fill channel cut 245. A profile of sacrificial plug 250 corresponds with a profile of channel cut 245 (e.g., sacrificial plug 250 may have tapered sidewalls). In some embodiments, such as depicted, patterned hard mask 242 may remain after forming channel cut 245, sacrificial material 250′ may be formed over patterned hard mask 242, sacrificial material 250′ may fill opening 243 in patterned hard mask 242, and the planarization process may remove sacrificial material 250′ disposed over patterned hard mask 242 (i.e., patterned hard mask 242 may function as a planarization stop layer, such as a CMP stop). In such embodiments, sacrificial plug 250 is further disposed in patterned hard mask 242. A composition of sacrificial material 250′ (and thus sacrificial plug 250) is different than a composition of patterned hard mask 242 and dummy gate bulk 236 to achieve etch selectivity. For example, sacrificial material 250′ and sacrificial plug 250 may be formed of a dielectric material that enables etching/removal of patterned hard mask 242 (e.g., a silicon nitride mask) and/or dummy gate bulk 236 (e.g., polysilicon) without (or negligibly) etching/removing sacrificial material 250′/sacrificial plug 250, or vice versa. The dielectric material may also enable removal of sacrificial plug 250 without (or negligibly) removing semiconductor layers 220. In some embodiments, sacrificial material 250′ is an oxide material, and sacrificial plug 250 is an oxide plug (e.g., a silicon oxide plug or a metal oxide plug). In some embodiments, sacrificial plug 250 is formed of a same material as sacrificial layers 215 and/or dummy gate dielectric 234. In some embodiments, sacrificial plug 250 is formed of a different material than sacrificial layers 215 and/or dummy gate dielectric 234. In some embodiments, sacrificial material 250′ and/or sacrificial plug 250 has a multilayer structure.

In some embodiments, referring to FIG. 5M, FIG. 6M, and FIGS. 10A-10D, a continuous poly on diffusion edge (CPODE) patterning process may be performed after channel cut (e.g., FIGS. 5B-5L and FIGS. 6B-6L) and before replacing dummy gate stack 232 with gate stack 132 (e.g., FIG. 5°-5Q and FIG. 6°-6Q). Such embodiments may be referred to as a CPODE-first process. Referring to FIG. 10A, gate structure 130 may be one of multiple gate structures 130 disposed over and spanning active region 160, gate structures 130 may be active gate structures, and device 100 may further include dummy gate structures 230 disposed over and spanning active region 160. In the depicted embodiment, dummy gate structures 230 are disposed along and/or at edges of active region 160, and gate structures 130 are disposed between dummy gate structures 230. “Active gate structure,” “active gate stack,” and “active gate” generally refers to an electrically functional gate structure (and/or gate stack), whereas “dummy gate structure” generally refers to an electrically non-functional gate structure (and/or gate stack). A dummy gate structure may mimic physical properties of an active gate structure, such as physical dimensions and/or layers of the active gate structure, yet is electrically inoperable (i.e., applying voltage to the dummy gate structure does not enable current to flow through channels and/or between source/drains). At the stage of fabrication depicted in FIG. 10A (which corresponds with the stage of fabrication of FIG. 5L and FIG. 6L), both active gate structures 130 and dummy gate structures 230 include dummy gate stacks 232.

As part of the CPODE process, dummy gate stacks 232 of dummy gate structures 230 are replaced with isolation structures (e.g., dielectric material). In some embodiments, referring to FIG. 10B, FIG. 5M, and FIG. 6M, a portion of sacrificial plug 250 disposed in patterned hard mask 242 may be replaced with a hard mask plug 252 before removing dummy gate stacks 232 from dummy gate structures 230. In some embodiments, hard mask plug 252 is formed by removing sacrificial plug 250 from patterned hard mask 242 (e.g., by etching back sacrificial plug 250 (e.g., an oxide material)), thereby re-opening opening 243 in patterned hard mask 242 and depositing a hard mask material that fills opening 243 of patterned hard mask 242. The hard mask material (and thus hard mask plug 252) may be formed of a same material (having a same composition or a different composition than) or a different material than patterned hard mask 242. For example, hard mask plug 252 may be a nitride plug, such as a silicon nitride plug. In some embodiments, a planarization process and/or an etch back process may be performed on the hard mask material to reduce a thickness thereof, such that a thickness of hard mask plug 252 is substantially the same as a thickness of patterned hard mask 242.

Referring to FIG. 10C, the CPODE process may include forming trenches 253 that extend through a portion of dummy gate structures 230 and into substrate 105. Trenches 253 may be formed by removing dummy gate stack 232 from gate structure 230 (e.g., dummy gate bulk 236 and dummy gate dielectric thereof), multilayer stack 210 thereunder, and a portion of protrusion 105′ and/or substrate 105 thereunder. Referring to FIG. 10D, the CPODE process may include filling trenches 253 with isolation structures 254, such as dielectric structures. In some embodiments, isolation structures 254 may be formed of a single dielectric layer. In some embodiments, isolation structures 254 may be formed of multiple dielectric layers. Isolation structures 254 may be formed by depositing one or more dielectric materials over device 100 (e.g., over patterned hard mask 242) that fill trenches 253 and performing a planarization process. In some embodiments, the planarization process removes the one or more dielectric materials from over patterned hard mask 242, which may function as a planarization stop layer. In some embodiments, before forming trenches 253, a patterning process may be performed to form a patterning layer over patterned hard mask 242, and the patterning layer has openings therein that overlap dummy gate structures 230. An etching process may use the patterning layer to form openings in patterned hard mask 242 that expose dummy gate structures 230 (e.g., dummy gate stacks 232 thereof) and subsequently form trenches 253. In some embodiments, the hard mask plug 252 is formed by a portion of the patterning layer. In some embodiments, before forming trenches 253, a patterning process may be performed to form openings in patterned hard mask 242 that expose dummy gate structures 230 (e.g., dummy gate stacks 232 thereof), and patterned hard mask 242 may be used an etch mask when forming trenches 253.

Referring to FIG. 5N and FIG. 6N, patterned hard mask 242 may be removed by a planarization process (e.g., CMP) and/or other suitable process. In some embodiments, dielectric layer 170 (e.g., ILD layer 174 and/or CESL 172 thereof) and/or gate spacers 138 may function as a planarization stop layer. In some embodiments, the CPODE process is performed after forming gate stack 132 (referred to as a CPODE-last process). In such embodiments, processing associated with FIG. 5M and FIG. 6M may be omitted when fabricating device 100.

Referring to FIG. 5O and FIG. 6O, dummy gate bulk 236 is removed from gate structure 130 to form a gate opening 255. Gate opening 255 exposes channel regions, which include semiconductor layers 220, sacrificial layers 215, and sacrificial plugs 250. In some embodiments, such as depicted in FIG. 6°, dummy gate dielectric 234 remains over semiconductor layers 220, sacrificial layers 215, and isolation structures 110. In some embodiments, an etching process selectively removes dummy gate bulk 236 (e.g., poly gate) with negligible (to no) removal of dielectric layer 170 (e.g., ILD layer 174 and CESL 172), gate spacers 138, inner spacers 140, sacrificial layers 215, semiconductor layers 220, dummy gate dielectric 234, sacrificial plug 250, or combinations thereof. The etching process is a dry etch, a wet etch, other suitable etch, or combinations thereof. In some embodiments, such as depicted in FIG. 5O, an etchant and/or other removal means may be unable to reach and/or substantially remove dummy gate bulk 236 between sacrificial plug 250 and gate spacers 138, such that dummy gate bulk remnants 236′ may remain between sacrificial plug 250 and gate spacers 138. In some embodiments, the etching process may use a patterned mask layer as an etch mask, where the patterned mask layer covers dielectric layer 170 and/or gate spacers 138.

Referring to FIG. 5P and FIG. 6P, a channel release process may be performed to form a channel structure (e.g., semiconductor layers 120). The channel release process may include selectively removing sacrificial plug 250, dummy gate dielectric 234, and sacrificial layers 215 exposed by gate opening 255 to form gaps 258. For example, a respective gap 258 may be between semiconductor layer 220U and semiconductor layer 220M, a respective gap 258 may be between semiconductor layer 220M and semiconductor layer 220L, and a respective gap 258 may be between bottom semiconductor layer 220L and protrusion 105′ and/or substrate 105, thereby suspending semiconductor layers 220 in the channel regions. Removing sacrificial plug 250 may further provide semiconductor layer 220U with opening 245U therein, semiconductor layer 220M with opening 245M therein, and semiconductor layer 220L with opening 245L therein. The channel release process thus re-opens holes in semiconductor layers 220.

In the depicted embodiment, three semiconductor rings (e.g., semiconductor layers 220) are vertically stacked along the z-direction and suspended over protrusion 105′ after the channel release process. Suspended semiconductor layers 220 having ring-shaped structures may provide channels of transistor T through which current may flow between source/drain structures 150. Semiconductor layers 220 may thus be referred to as semiconductor layers 120, channel layers 120, channels, a channel structure, or combinations thereof. In some embodiments, the channel release process includes an etching process that selectively etches sacrificial plug 250, dummy gate dielectric 234, and sacrificial layers 215 without (or negligibly) etching semiconductor layers 220 (120), protrusions 105′, isolation structures 110, gate spacers 138, inner spacers 140, dielectric layer 170 (e.g., ILD layer 174 and/or CESL 172 thereof), or combinations thereof. An etchant may be selected for the etching process that etches oxide (i.e., sacrificial plug 250, dummy gate dielectric 234, and sacrificial layers 215) at a higher rate than silicon (i.e., semiconductor layers 220 and protrusions 105′) and other dielectric materials (i.e., gate spacers 138 and inner spacers 140) (i.e., the etchant has a high etch selectivity with respect to oxide). In some embodiments, a single etchant may remove sacrificial plug 250, dummy gate dielectric 234, and sacrificial layers 215. In some embodiments, the etching process may be a multistep process that implements different etchants to separately remove sacrificial plug 250, dummy gate dielectric 234, and sacrificial layers 215. The etching process is a dry etch, a wet etch, other suitable etching process, or combinations thereof. In some embodiments, the etching process may remove dummy gate bulk remnants 236′. In some embodiments, before the etching process, an oxidation process may convert dummy gate bulk remnants 236′ (e.g. polysilicon) into oxide remnants, such that the etching process may also remove the oxide remnants when removing sacrificial plug 250, dummy gate dielectric 234, sacrificial layers 215, or combinations thereof. In some embodiments, before the etching process, an oxidation process may convert sacrificial layers 215 into semiconductor oxide features (e.g., silicon germanium oxide), and the etching process then removes the semiconductor oxide features. In some embodiments, a separate etching process and/or other suitable removal process is performed to remove dummy gate bulk remnants 236′ before or after the etching process to remove sacrificial plug 250, dummy gate dielectric 234, sacrificial layers 215, or combinations thereof. In some embodiments, during and/or after removing sacrificial plug 250, dummy gate dielectric 234, sacrificial layers 215, or combinations thereof, an etching process may be performed to modify a profile of semiconductor layers 220 to provide the channel structure (e.g., semiconductor layers 120) with target dimensions and/or target shapes. For example, the etching process may provide semiconductor segment 220U-1, semiconductor segment 220U-2, semiconductor segment 220M-1, semiconductor segment 220M-2, semiconductor segment 220L-1, semiconductor segment 220L-2, or combinations thereof with cylindrical-shaped profiles (e.g., nanowires), rectangular-shaped profiles (e.g., nanobars), or other shaped profile (see, e.g., FIG. 6P).

Referring to FIG. 5Q, FIG. 6Q, and FIGS. 1A-1C, gate stack 132 (e.g., gate dielectric 134 and gate electrode 136) is formed over the channel structure (e.g., semiconductor layers 120). Gate stack 132 fills gate opening 255, along with gaps 258. Gate stack 132 is disposed between gate spacers 138, between inner spacers 140, between semiconductor layers 120 (220), and between bottom semiconductor layers 120 (220) and protrusion 105′. Gate stack 132 may surround and/or wrap semiconductor layers 120 (e.g., in the Y-Z plane) (FIG. 6Q). Because semiconductor layers 120 (220) are configured as semiconductor rings, gate stack 132 also fills openings in and extends through semiconductor layers 120 (220). For example, gate stack 132 fills opening 245U, opening 245M, and opening 245L, such that gate stack 132 extends through semiconductor layer 120U (220U), semiconductor layer 120M (220M), and semiconductor layer 120L (220L). In a cross-sectional view through a non-segmented portion of semiconductor layers 120 (see, e.g., FIG. 1C), semiconductor layers 120 (220) (e.g., semiconductor segment 120U-1 (220U-1), semiconductor segment 120U-2 (220U-2), semiconductor segment 120M-1 (220M-1), semiconductor segment 120M-2 (220M-2), semiconductor segment 120L-1 (220L-1), and semiconductor segment 120L-2 (220L-2) thereof) extend continuously along the active region lengthwise direction between source/drain structures 150. In a cross-sectional view through a segmented portion of semiconductor layers 120 (220) (see, e.g., FIG. 5Q), gate stack 132 extends through semiconductor layers 120 (220), and gate stack 132 is disposed between respective semiconductor segments of semiconductor layers 120 (220) along the active region lengthwise direction (e.g., between semiconductor segments 120U-3 (220U-3), semiconductor segments 120M-3 (220M-3), and semiconductor segments 120L-3 (220L-3)).

With such configuration, gate stack 132 engages more than two sides of semiconductor layers 120 having ring-shaped profiles. For example, as depicted in FIG. 6Q, which includes a fragmentary top view of semiconductor layer 120U (220U) along line 1-1′ thereof, gate stack 232 is disposed on and engages four sidewalls, instead of two sidewalls, of semiconductor layer 120U—each sidewall of semiconductor segment 120U-1 (220U-1) and each sidewall of semiconductor segment 120U-2 (220U-2). Gate stack 132 further is disposed on and engages two tops and two bottoms, instead of one top and one bottom, of semiconductor layer 120U—a top and a bottom of semiconductor segment 120U-1 (220U-1) and a top and a bottom of semiconductor segment 120U-2 (220U-2). Gate stack 132 is similarly disposed on and engages semiconductor layer 220M and semiconductor layer 220L. Such configuration may improve gate control and reduce short channel effects, such as described herein.

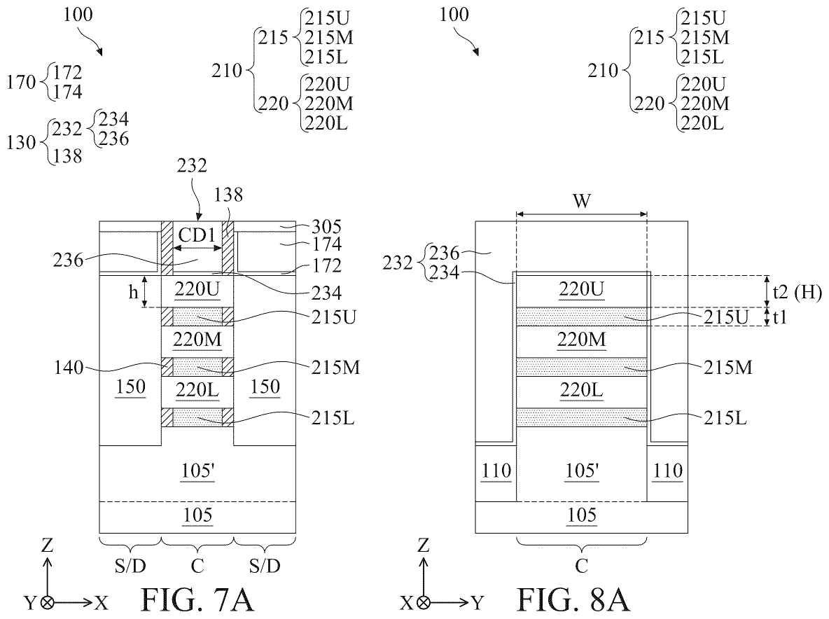

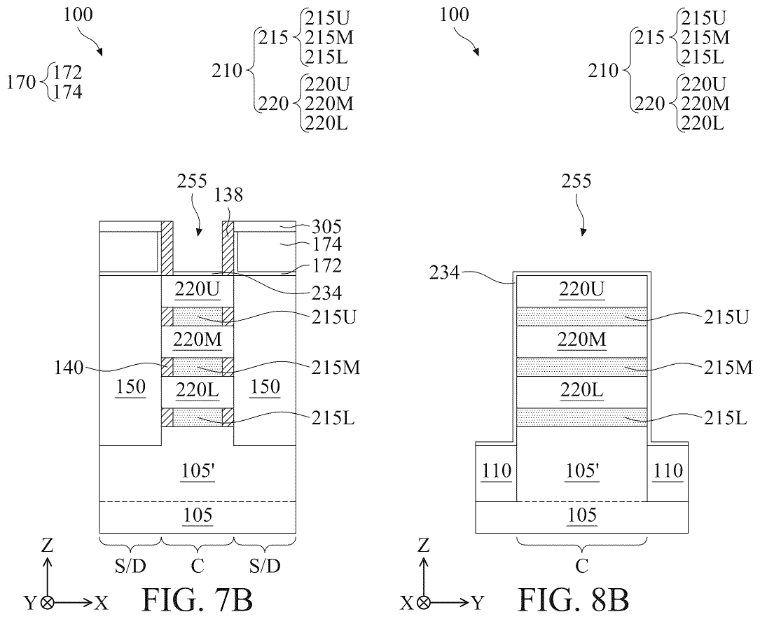

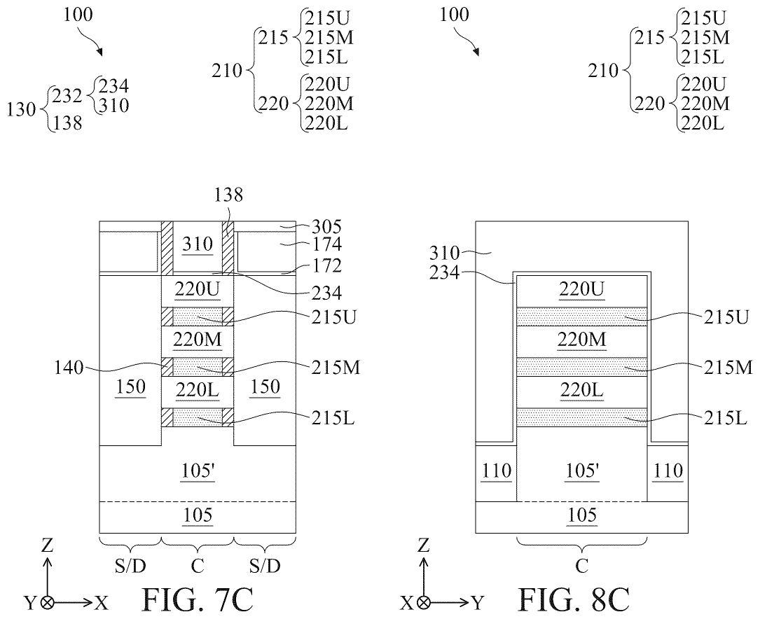

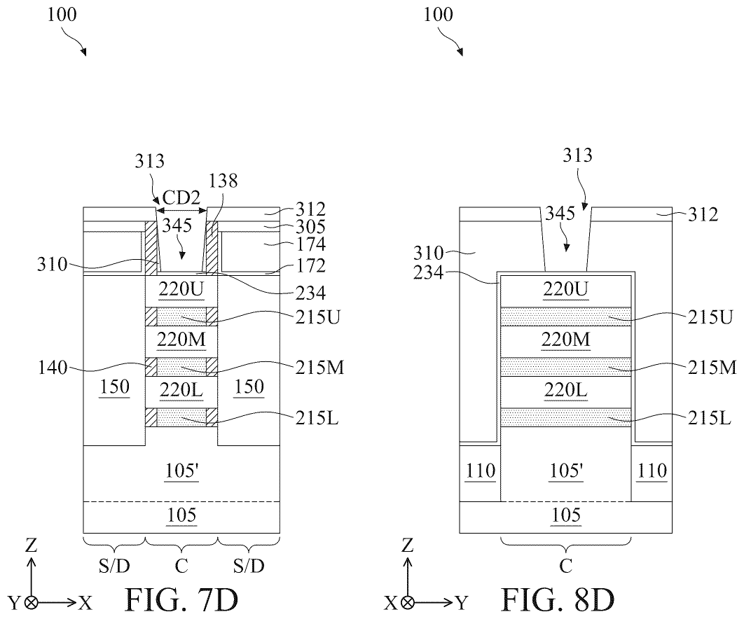

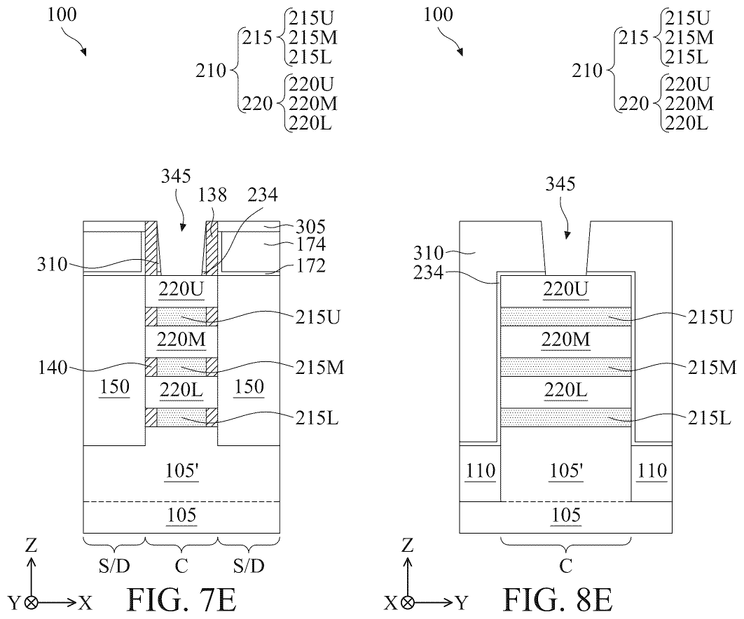

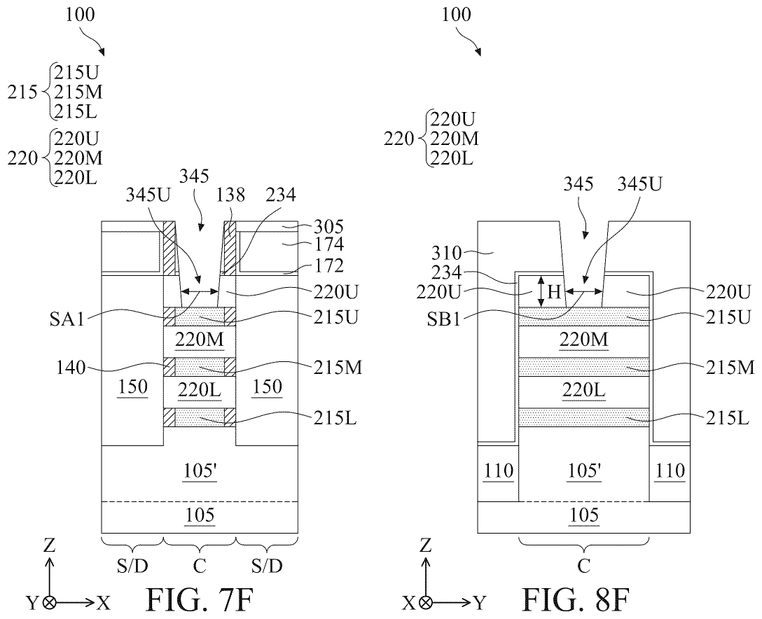

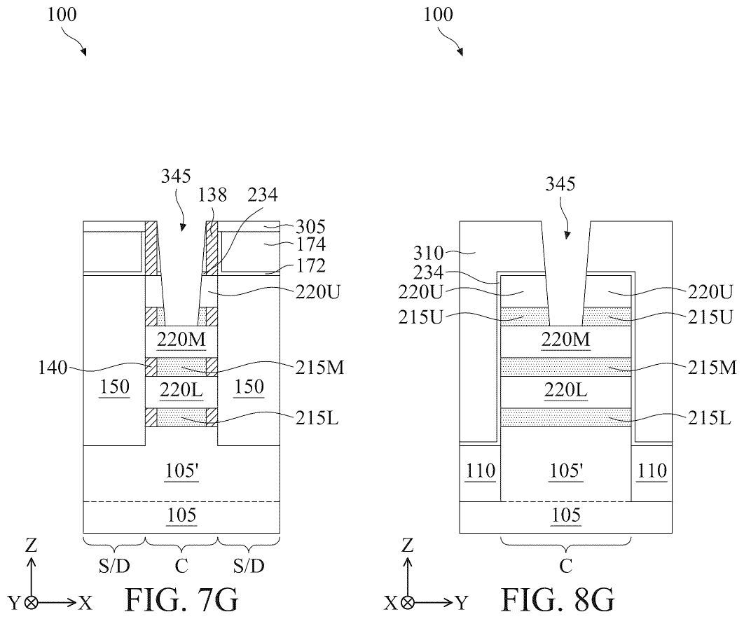

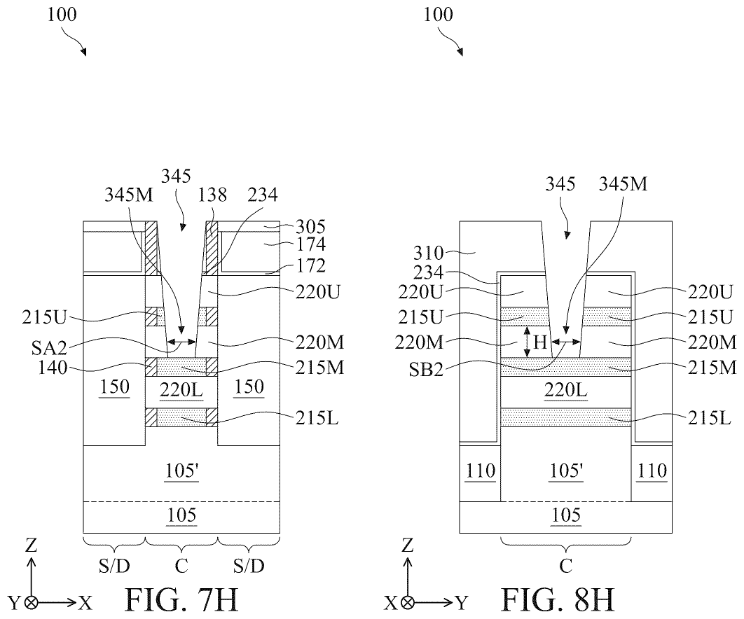

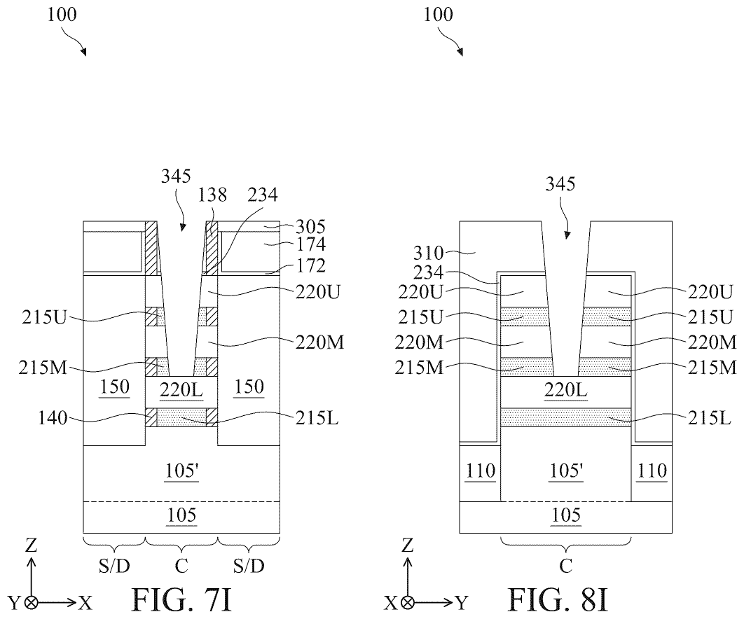

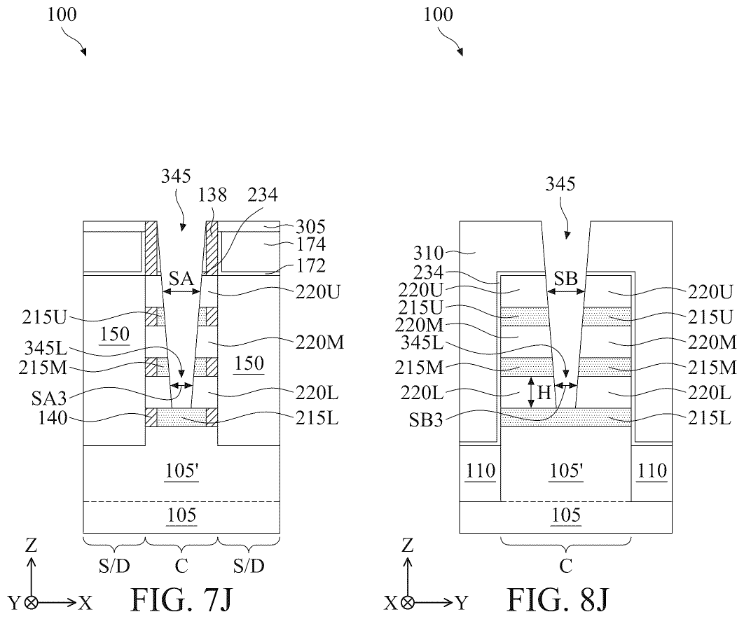

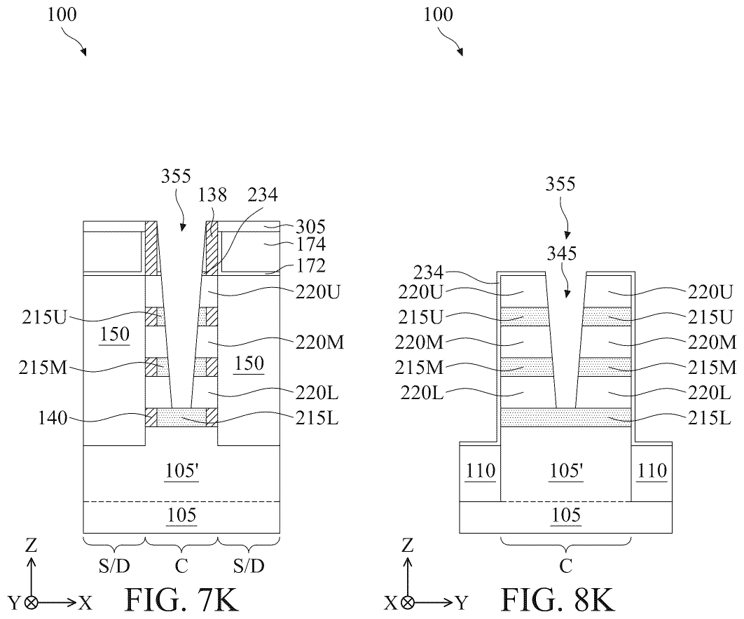

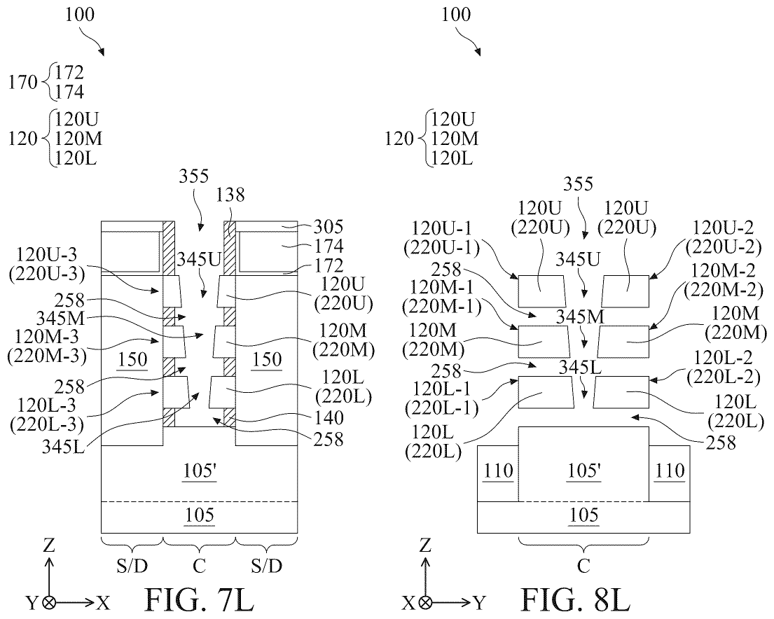

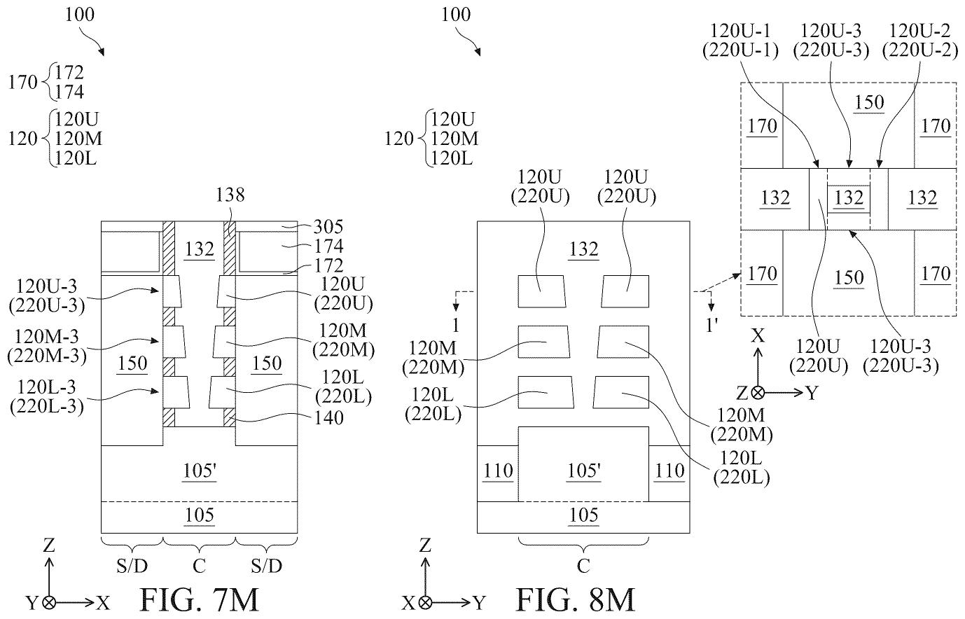

FIGS. 7A-7M are diagrammatic cross-sectional views of device 100, in portion or entirety, along line E-E of FIG. 1A at various stages of another fabrication process according to various aspects of the present disclosure. FIGS. 8A-8M correspond with the various fabrication stages of FIGS. 7A-7M, respectively, and FIGS. 8A-8M are diagrammatic cross-sectional views of device 100, in portion or entirety, along line D-D of FIG. 1A according to various aspects of the present disclosure. The fabrication process of FIGS. 7A-7M and FIGS. 8A-8M is similar in many respects to the fabrication process of FIGS. 5A-5Q and FIGS. 6A-6Q. Accordingly, similar features in FIGS. 5A-5Q, FIGS. 6A-6Q, FIGS. 7A-7M, and FIGS. 8A-8M are identified by the same reference numbers for clarity and simplicity. FIGS. 7A-7M and FIGS. 8A-8M are discussed concurrently herein for ease of description and understanding. FIGS. 7A-7M and FIGS. 8A-8M have been simplified for the sake of clarity to better understand the inventive concepts of the present disclosure. Additional features may be added in device 100 and/or the fabrication process thereof, and some of the features described below may be replaced, modified, or eliminated in other embodiments of device 100 and/or the fabrication process thereof.

Referring to FIG. 7A and FIG. 8A, device 100 may be at an intermediate stage of processing, such as described above with reference to FIG. 5A and FIG. 6A. In some embodiments, a mask 305 may be disposed and/or formed over dielectric layer 170. Mask 305 includes a material that enables etch selectivity during subsequent processing, such as during a gate replacement process, a channel cut process, a channel release process, or combinations thereof. Mask 305 may cover and protect dielectric layer 170. In some embodiments, mask 305 is a silicon nitride layer, a metal nitride layer, a metal oxide layer, or combinations thereof. The silicon nitride layer and/or the metal nitride layer may further include carbon and/or oxygen. The metal oxide layer may further include nitrogen and/or carbon. In some embodiments, mask 305 has a multilayer structure. Mask 305 may be formed by etching back and/or recessing dielectric layer 170, depositing a mask material over device 100, and performing a planarization process that removes the mask material from over gate structure 130. Mask 305 and gate structure 130 may thus form a top of device 100. In some embodiments, gate spacers 138 and/or dummy gate stack 232 may function as a planarization stop layer. The present disclosure further contemplates embodiments where mask 305 is formed over dielectric layer 170 during the fabrication process described with reference to FIGS. 5A-5Q and FIGS. 6A-6Q.

The fabrication process described with reference to FIGS. 7A-7M and FIGS. 8A-8M segments and/or cuts semiconductor layers 220 during the gate replacement process, instead of before the gate replacement process. Referring to FIG. 7B and FIG. 8B, dummy gate bulk 236 is removed from gate structure 130 to form gate opening 255. Gate opening 255 exposes channel regions, which include semiconductor layers 220 and sacrificial layers 215. It is noted that, in the depicted embodiment, sacrificial plug 250 is not yet formed, so gate opening 255 does not also expose sacrificial plug 250. In some embodiments, such as depicted, dummy gate dielectric 234 remains over semiconductor layers 220, sacrificial layers 215, and isolation structures 110. In some embodiments, an etching process selectively removes dummy gate bulk 236 (e.g., poly gate) with negligible (to no) removal of mask 305, gate spacers 138, inner spacers 140, sacrificial layers 215, semiconductor layers 220, dummy gate dielectric 234, or combinations thereof. The etching process is a dry etch, a wet etch, other suitable etch, or combinations thereof. In some embodiments, the etching process may use a patterned mask layer as an etch mask, where the patterned mask layer covers dielectric layer 170 and/or gate spacers 138.

Referring to FIG. 7C and FIG. 8C, an antireflective coating (ARC) 310 is formed in gate opening 255. In other words, antireflective coating 310 replaces dummy gate bulk 236. Antireflective coating 310 may be formed of an antireflective material that is resistant to an etching process performed on underlying layers, such as semiconductor layers 220 and/or sacrificial layers 215. A composition of antireflective coating 310 is thus different than a composition of semiconductor layers 220 and sacrificial layers 215. The composition of antireflective coating 310 may be different than a composition of dummy gate dielectric 234. In some embodiments, antireflective coating 310 is a bottom antireflective coating (BARC). In some embodiments, antireflective coating 310 includes an organic material. For example, antireflective coating 310 may be a carbon-rich polymer layer, which may include carbon and hydrogen and/or oxygen. In some embodiments, the carbon-rich polymer layer is a CᵢHⱼOₖ layer. In another example, antireflective coating 310 may be a silicon-rich polymer layer, which may include silicon and carbon, hydrogen, oxygen, or combinations thereof. In some embodiments, the silicon-rich polymer layer is an SiCₓH_{y}O_{z} layer. In some embodiments, antireflective coating 310 is free of silicon. In some embodiments, antireflective coating 310 is formed by a spin coating process that is, optionally, followed by a baking process. In some embodiments, a planarization process may be performed after depositing and/or spin-coating an antireflective coating material over device 100 that fills gate opening 255. The planarization process may remove the antireflective coating material disposed over mask 305 and/or gate spacers 138.

Referring to FIGS. 7D-7J and FIGS. 8D-8J, segmenting of semiconductor layers 220 may include forming at least one channel cut 345 in multilayer stack 210 that extends through at least one of semiconductor layers 220. In some embodiments, such as depicted, channel cut 345 extends partially through multilayer stack 210. For example, channel cut 345 extends through antireflective coating 310, dummy gate dielectric 234, semiconductor layer 220U, sacrificial layer 215U, semiconductor layer 220M, sacrificial layer 215M, and semiconductor layer 220L. Channel cut 345 thus extends through all semiconductor layers 220 but stops at and exposes sacrificial layer 215L. Channel cut 345 is configured similar to channel cut 245 described above with reference to FIGS. 5D-5J and FIGS. 6D-6J, and channel cut 345 segments semiconductor layers 220 in a similar manner as channel cut 245, such as described above. Channel cut 345 provides semiconductor layer 220U with an opening 345U, semiconductor layer 220M with an opening 345M, and semiconductor layer 220L with an opening 345L, which may be similar to opening 245U, opening 245M, and opening 245L, respectively, described above.

An etching process may be performed to form channel cut 345. The etching process may include and/or be a dry etch, a wet etch, other suitable etching process, or combinations thereof. In some embodiments, the etching process is a multistep etch. For example, the etching process may alternate etchants and/or tune other etch parameters (e.g., etch time, etch temperature, etch pressure, flow rate of etchants, etc.) to separately and alternately remove antireflective coating 310 (FIG. 7D and FIG. 8D), dummy gate dielectric 234 (FIG. 7E and FIG. 8E), semiconductor layer 220U (FIG. 7F and FIG. 8F), sacrificial layer 215U (FIG. 7G and FIG. 8G), semiconductor layer 220M (FIG. 7H and FIG. 8H), sacrificial layer 215M (FIG. 7I and FIG. 8I), and semiconductor layer 220L (FIG. 7J and FIG. 8J). In some embodiments, the etching process includes selectively removing antireflective coating 310 with respect to dummy gate dielectric 234 (FIG. 7D and FIG. 8D)(e.g., a first etch step); selectively removing dummy gate dielectric 234 with respect to antireflective coating 310 and semiconductor layer 220U (FIG. 7E and FIG. 8E) (e.g., a second etch step); selectively removing semiconductor layer 220U with respect to antireflective coating 310, dummy gate dielectric 234, and sacrificial layer 215U (FIG. 7F and FIG. 8F) (e.g., a third etch step); selectively removing sacrificial layer 215U with respect to antireflective coating 310, semiconductor layer 220U, and semiconductor layer 220M (FIG. 7G and FIG. 8G) (e.g., a fourth etch step); selectively removing semiconductor layer 220M with respect to antireflective coating 310, dummy gate dielectric 234, sacrificial layer 215U, and sacrificial layer 215M (FIG. 7H and FIG. 8H) (e.g., a fifth etch step); selectively removing sacrificial layer 215M with respect to antireflective coating 310, semiconductor layer 220U, semiconductor layer 220M, and semiconductor layer 220L (FIG. 7I and FIG. 8I) (e.g., a sixth etch step); and selectively removing semiconductor layer 220L with respect to antireflective coating 310, dummy gate dielectric 234, sacrificial layer 215U, sacrificial layer 215M, and sacrificial layer 215L (FIG. 7J and FIG. 8J) (e.g., a seventh etch step). In some embodiments, dummy gate dielectric 234 and sacrificial layers 215 are formed of oxide (Ox) (having the same composition or different compositions), semiconductor layers 220 are formed of silicon (Si), and the etching process may be an ARC/Ox/Si/Ox/Si/Ox/Si etch. The etching process may use different etchants to separately remove ARC, oxide, and silicon. For example, the etching process may implement a first etchant to selectively remove ARC without (or negligibly) removing oxide and silicon, a second etchant to selectively remove oxide without (or negligibly) removing ARC and silicon, and a third etchant to selectively remove silicon without (or negligibly) removing ARC and oxide. In some embodiments, multiple etching steps of the etching process are performed in a same process chamber. For example, when the etching process is an ARC/Ox/Si/Ox/Si/Ox/Si etch, device 100 may be exposed to the first etchant, the second etchant, and the third etchant in a same process chamber. In some embodiments, after each etch step, a purge process may be performed to remove a given etchant of a respective etch step and any byproducts before performing a next etch step in the same process chamber.

In some embodiments, the etching process may further selectively remove antireflective coating 310, dummy gate dielectric 234, semiconductor layers 220, sacrificial layers 215, or combinations thereof relative to mask 305. In other words, channel cut 345 may be formed without (or negligibly) removing mask 305. In some embodiments, as depicted in FIG. 7D and FIG. 8D, a patterning layer 312 may be formed over device 100 before etching antireflective coating 310, and the etching process may use patterning layer 312 as an etch mask. For example, patterning layer 312 may have an opening 313 therein that overlaps and/or exposes a portion of antireflective coating 310 over multilayer stack 210, and the etching process may remove the exposed portion of antireflective coating 310 (i.e., that portion not covered by patterning layer 312). Opening 313 may be similar to opening 243 described above. For example, opening 313 may have critical dimension D2. In some embodiments, patterning layer 312 is a patterned resist layer, which may be removed by the etching process and/or a resist stripping process. In some embodiments, such as depicted, patterning layer 312 is removed before channel cut 345 is extended into dummy gate dielectric 234. In some embodiments, patterning layer 312 is removed during the etching process, such that patterning layer 312 (or a portion thereof) may remain over antireflective coating 310 during the etching of dummy gate dielectric 234, semiconductor layer 220U, sacrificial layer 215U, semiconductor layer 220M, sacrificial layer 215M, semiconductor layer 220L, or combinations thereof.

Referring to FIG. 7K and FIG. 8K, antireflective coating 310 is removed from gate structure 130 to form a gate opening 355. Gate opening 355 exposes channel regions, which include semiconductor layers 220 and sacrificial layers 215. In some embodiments, such as depicted, dummy gate dielectric 234 remains over semiconductor layers 220, sacrificial layers 215, and isolation structures 110. In some embodiments, an etching process selectively removes antireflective coating 310 with negligible (to no) removal of mask 305, gate spacers 138, inner spacers 140, sacrificial layers 215, semiconductor layers 220, dummy gate dielectric 234, or combinations thereof. The etching process is a dry etch, a wet etch, other suitable etch, or combinations thereof. In the depicted embodiment, since channel cut 345 is formed after removing dummy gate bulk 236, channel cut 345 is present in multilayer stack 210 during removal of antireflective coating 310 and after removal of antireflective coating 310. In other words, processing associated with forming a sacrificial plug, such as sacrificial plug 250, in channel cut 345 may be omitted in the fabrication process of FIGS. 7A-7M and FIGS. 8A-8M. In some embodiments, the etching process may use a patterned mask layer as an etch mask, where the patterned mask layer covers dielectric layer 170 and/or gate spacers 138.

Referring to FIG. 7L and FIG. 8L, a channel release process may be performed to form a channel structure (e.g., semiconductor layers 120), such as described with reference to FIG. 5P and FIG. 6P. The channel release process may include selectively removing dummy gate dielectric 234 and sacrificial layers 215 exposed by gate opening 255 to form gaps 258. In the depicted embodiment, since openings within semiconductor layers 220 (e.g., opening 345U, opening 345M, and opening 345L) are present before the channel release process, the channel release process may connect the openings within semiconductor layers 220 with gaps 258 without re-opening the openings, such as described above. Referring to FIG. 7M, FIG. 8M, and FIGS. 1A-1C, gate stack 132 (e.g., gate dielectric 134 and gate electrode 136) is formed over the channel structure (e.g., semiconductor layers 120), such as described above with reference to FIG. 5Q and FIG. 6Q. Gate stack 132 may fill gate opening 355, gaps 258, and openings within semiconductor layers 220 (e.g., opening 345U, opening 345M, and opening 345L). The fabrication process described with reference to FIGS. 7A-7M and FIGS. 8A-8M may further implement a CPODE first process or a CPODE last process. In the CPODE first process embodiments, the CPODE process may be performed before replacing dummy gate bulk 236 with antireflective coating 310. In the CPODE last process embodiments, the CPODE process may be performed after replacing dummy gate stack 232 with gate stack 132.

FIG. 11 is a diagrammatic top view of a device layout, in portion or entirety, that may be implemented when fabricating device 100 according to various aspects of the present disclosure. In the device layout, device 100 may include a CMOS transistor, and transistor T may form a portion of the CMOS transistor, such as an n-type transistor or a p-type transistor thereof. In such embodiments, device 100 may include two active regions 160, gate structures 130 may span both active regions 160, and dummy gate structures 230 may span both active regions 160. In some embodiments, upper active region 160 may be configured for n-type transistors (e.g., a p-well may be formed in substrate 105 and source/drain structures 150 may be n-type source/drains), and lower active region may be configured for p-type transistors (e.g., an n-well may be formed in substrate 105 and source/drain structures 150 may be p-type source/drains), or vice versa. A channel cut layout may overlay the device layout, and the channel cut layout may include channel cuts 390, which may define a location and/or dimensions of channel cuts, such as channel cut 245 and/or channel cut 345, when segmenting channels of device 100. For example, the channel cut layout may be used to form channel cut openings in a patterning layer, such as opening 243 in patterned hard mask 242 and/or opening 313 in patterning layer 312. In some embodiments, channels of n-type transistors and channels of p-type transistors may be segmented at the same time. In some embodiments, channels of n-type transistors and channels of p-type transistors may be segmented at different times. The etching process implemented during channel segmentation may be configured to minimize loss of gate spacers 138 and/or inner spacers 140. FIG. 11 has been simplified for the sake of clarity to better understand the inventive concepts of the present disclosure. Additional features may be added in the device layout of FIG. 11, and some of the features described below may be replaced, modified, or eliminated in other embodiments the device layout of FIG. 11.

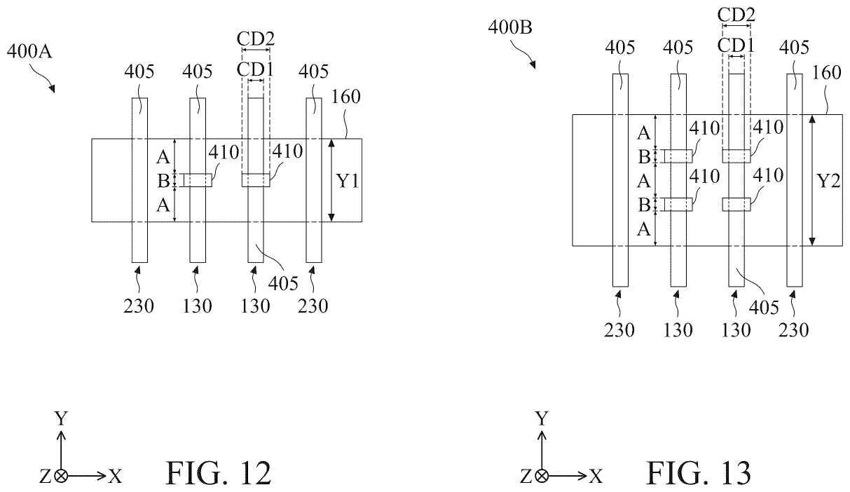

FIGS. 12-14 are diagrammatic top views of channel cut layouts, in portion or entirety, that may be implemented when fabricating device 100 (e.g., when forming channel cut 245 and/or channel cut 345), according to various aspects of the present disclosure. For example, the channel cut layouts may be used to form channel cut openings in a patterning layer, such as opening 243 in patterned hard mask 242 and/or opening 313 in patterning layer 312, and the channel cut openings may define a location and/or dimensions of channel cuts, such as channel cut 245 and/or channel cut 345. The channel cut layouts of FIGS. 12-14 may be configured to provide different-sized devices with channel segments having the same widths. For example, the channel cut layouts may be implemented to segment nanosheets of different-sized devices into nanowires/nanobars having the same widths. In some embodiments, active region 160 has a width Y1 (e.g., along the y-direction) in a channel cut layout 400A (FIG. 12), a width Y2 (e.g., along the y-direction) in a channel cut layout 400B (FIG. 13), and a width Y3 (e.g., along the y-direction) in a channel cut layout 400C (FIG. 14). Width Y1, width Y2, and width Y3 are different. For example, width Y1 is less than width Y2, and width Y2 is less than width Y3. In channel cut layouts 400A-400C, gate lines 405 may be disposed over channel regions of active region 160, and gate lines 405 may extend substantially parallel to one another along the active region widthwise direction (e.g., the y-direction). Lengths of gate lines 405 (e.g., along the y-direction) are greater than the width of active region 160 (e.g., width Y1, width Y2, and/or width Y3), gate lines 405 correspond with gate stacks (e.g., dummy gate stacks 232 and/or gate stacks 132) of gate structures 130 and dummy gate structures 230, and gate lines 405 may define critical dimension CD1 (e.g., along the x-direction).

Channel cut layouts 400A-400C may define channel cuts 410 that overlap channel regions of active region 160, along with gate lines 405 disposed thereover. Channel cuts 410 have critical dimension D2 (e.g., along the x-direction), and channel cuts 410 have a width B along the active region widthwise direction (e.g., the y-direction). In channel cut layouts 400A-400C, a number of channel cuts 410 for a given channel region depends on a width of active region 160 and the number of channel cuts 410 is selected to provide channel segments having a same width, such as a width A, along the active region widthwise direction. For example, channel cut layout 400A may provide one channel cut 410 to segment a channel region having width Y1 into two channel segments having width A, channel cut layout 400B may provide two channel cuts 410 to segment a channel region having width Y2 into two channel segments having width A, and channel cut layout 400C may provide three channel cuts 410 to segment a channel region having width Y3 into three channel segments having width A. In such embodiments, channel cut layout 400A may be generated, drawn, and/or placed over a device layout according to a cut formula of Y1=2A+B, channel cut layout 400B may be generated, drawn, and/or placed over a device layout according to a cut formula of Y2=3A+2B, and channel cut layout 400C may be generated, drawn, and/or placed over a device layout according to a cut formula of Y3=4A+3B. The channel segments provided by channel cut layouts 400A-400C may be separated by width B, which may correspond with spacing SB.

In some embodiments, channel cut layout 400A may provide one channel cut to segment a nanosheet having width Y1 into two nanowires/nanobars having width A and separated by width B (e.g., spacing SB is about width B). In some embodiments, channel cut layout 400B may provide two channel cuts to segment a nanosheet having width Y2 into three nanowires/nanobars having width A and separated by width B. In some embodiments, channel cut layout 400C may provide three channel cuts to segment a nanosheet having width Y3 into four nanowires/nanobars having width A and separated by width B. In some embodiments, channel cut layouts 400A-400C may be implemented together to simultaneously segment channels of multiple devices having different active region widths, such that the multiple devices are simultaneously provided with the same channel widths. In some embodiments, channel cut layouts 400A-400C may be implemented to separately segment channels of multiple devices having different active region widths, thereby providing multiple devices with the same channel widths. FIGS. 12-14 have been simplified for the sake of clarity to better understand the inventive concepts of the present disclosure. Additional features may be added in the channel cut layouts of FIGS. 12-14, and some of the features described below may be replaced, modified, or eliminated in other embodiments the channel cut layouts of FIGS. 12-14.

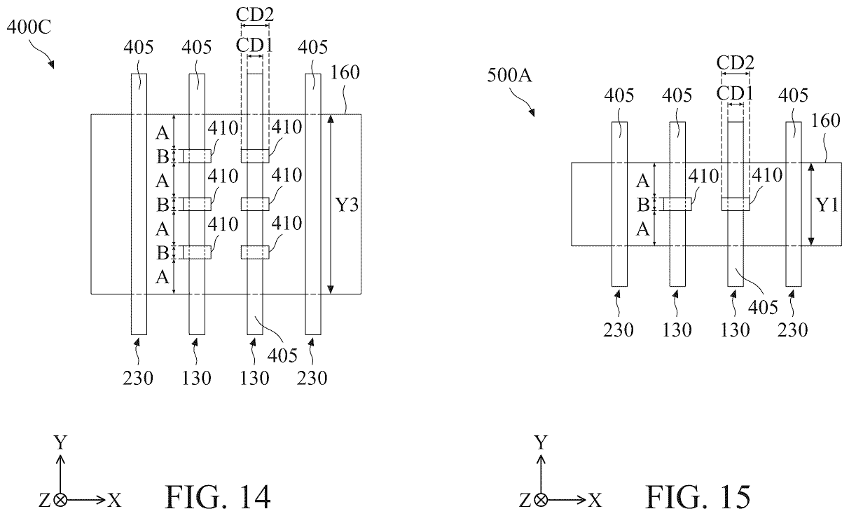

FIGS. 15-17 are diagrammatic top views of other channel cut layouts, in portion or entirety, that may be implemented when fabricating device 100 (e.g., when forming channel cut 245 and/or channel cut 345), according to various aspects of the present disclosure. For example, the channel cut layouts may be used to form channel cut openings in a patterning layer, such as opening 243 in patterned hard mask 242 and/or opening 313 in patterning layer 312, and the channel cut openings may define a location and/or dimensions of channel cuts, such as channel cut 245 and/or channel cut 345. The channel cut layouts of FIGS. 15-17 (e.g., a channel cut layout 500A, a channel cut layout 500B, and a channel cut 500C) may be configured to provide different-sized devices with channel segments having variable widths. For example, the channel cut layouts may be implemented to segment nanosheets of different-sized devices into nanowires/nanobars having the same and/or different widths. Channel cut layouts 500A-500C are similar in many respects to channel cut layouts 400A-400C. Accordingly, similar features in FIGS. 12-14 and FIGS. 15-17 are identified by the same reference numbers for clarity and simplicity. FIGS. 15-17 have been simplified for the sake of clarity to better understand the inventive concepts of the present disclosure. Additional features may be added in the channel cut layouts of FIGS. 15-17, and some of the features described below may be replaced, modified, or eliminated in other embodiments the channel cut layouts of FIGS. 15-17.

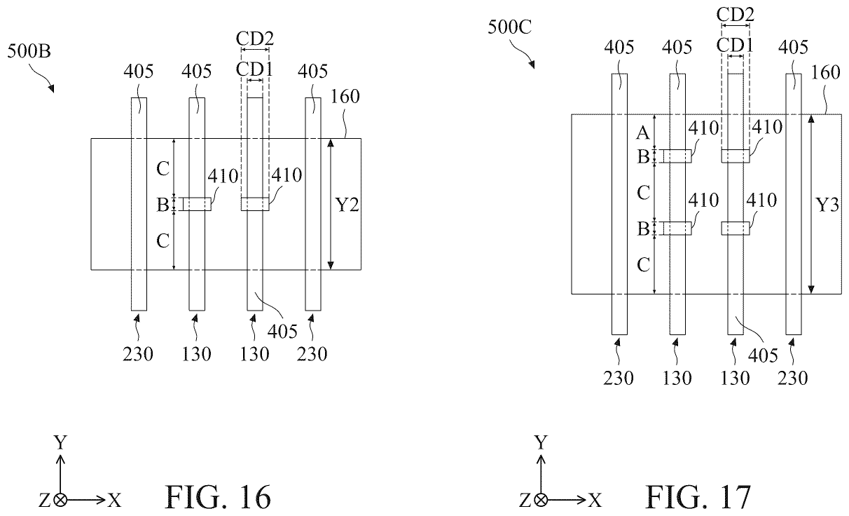

In FIGS. 15-17, active region 160 has width Y1 in channel cut layout 500A (FIG. 15), width Y2 in channel cut layout 500B (FIG. 16), and width Y3 in channel cut layout 500C (FIG. 14). In channel cut layouts 500A-500C, gate lines 405 may be disposed over channel regions of active region 160, and channel cut layouts 500A-500C may define channel cuts 410 having width B that overlap channel regions of active region 160, along with gate lines 405 disposed thereover. In channel cut layouts 500A-500C, a number of channel cuts 410 for a given channel region may depend on a width of active region 160 and/or desired performance characteristics of its corresponding transistor, and the number of channel cuts 410 is selected to provide channel segments having variable widths, such as width A and/or a width C, along the active region widthwise direction. For example, channel cut layout 500A may provide one channel cut 410 to segment a channel region having width Y1 into two channel segments having width A, channel cut layout 500B may provide two channel cuts 410 to segment a channel region having width Y2 into two channel segments having width C, which is different than (e.g., greater than) width A, and channel cut layout 500C may provide two channel cuts 410 to segment a channel region having width Y3 into three channel segments, where one of the channel segments has width A and two of the channel segments have width C. In such embodiments, channel cut layout 500A may be generated, drawn, and/or placed over a device layout according to a cut formula of Y1=2A+B, channel cut layout 500B may be generated, drawn, and/or placed over a device layout according to a cut formula of Y2=2C+B, and channel cut layout 500C may be generated, drawn, and/or placed over a device layout according to a cut formula of Y3=2C+2B+A. The channel segments provided by channel cut layouts 500A-500C may be separated by width B, which may correspond with spacing SB. In some embodiments, fewer channel cuts 410 may provide better performance (e.g., by providing wider channel segments).

In some embodiments, channel cut layout 500A may provide one channel cut to segment a nanosheet having width Y1 into two nanowires/nanobars having width A and separated by width B. In some embodiments, channel cut layout 500B may provide one channel cut to segment a nanosheet having width Y2 into two nanowires/nanobars having width C and separated by width B. In some embodiments, channel cut layout 500C may provide two channel cuts to segment a nanosheet having width Y3 into three nanowires/nanobars separated by width B, where one of the nanowires/nanobars has width WA and two of the nanowires/nanobars have width C. In some embodiments, channel cut layouts 500A-500C may be implemented together to simultaneously segment channels of multiple devices having different active region widths, such that the multiple devices are simultaneously provided with various channel widths, which may be the same and/or different In some embodiments, channel cut layouts 500A-500C may be implemented to separately segment channels of multiple devices having different active region widths, thereby providing multiple devices with the various channel widths. In some embodiments, channel cuts 410 may have different widths (e.g., width B in channel layout 500A may be different than width B in channel layout 500B, which may be different than width B in channel layout 500C, to provide the channel segments with the different widths).

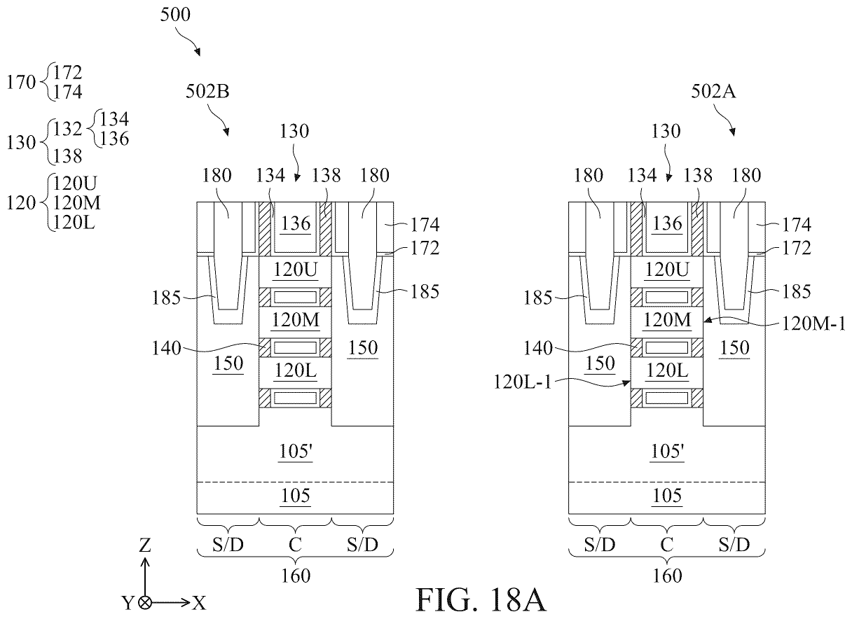

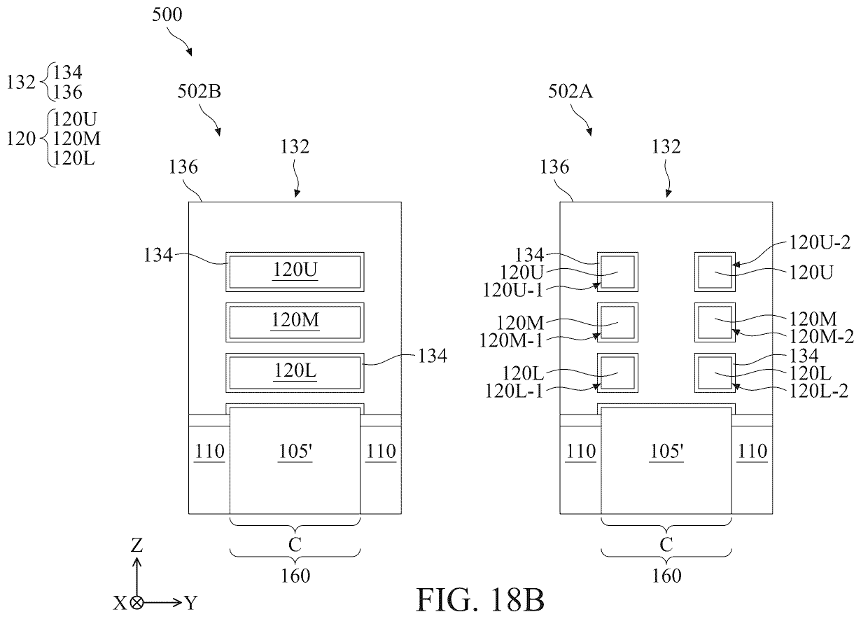

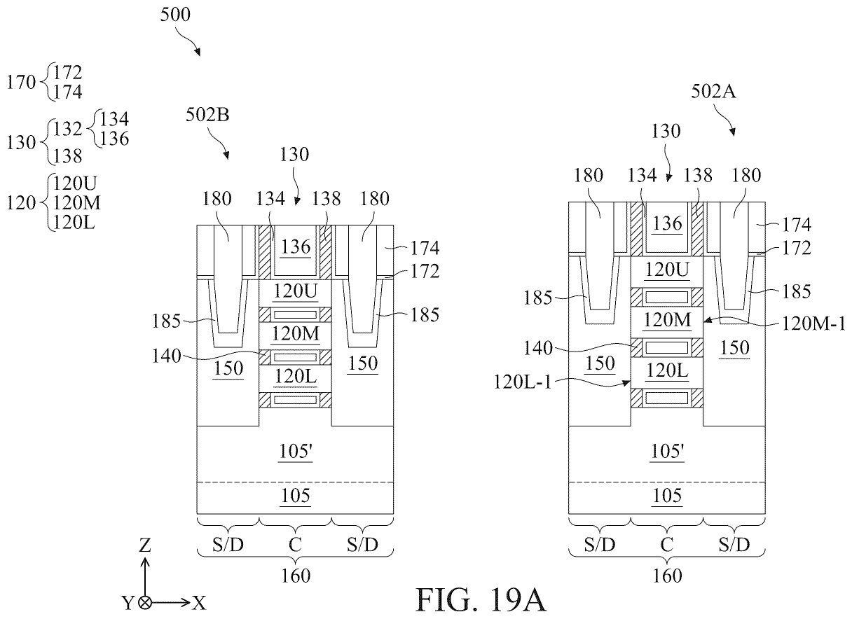

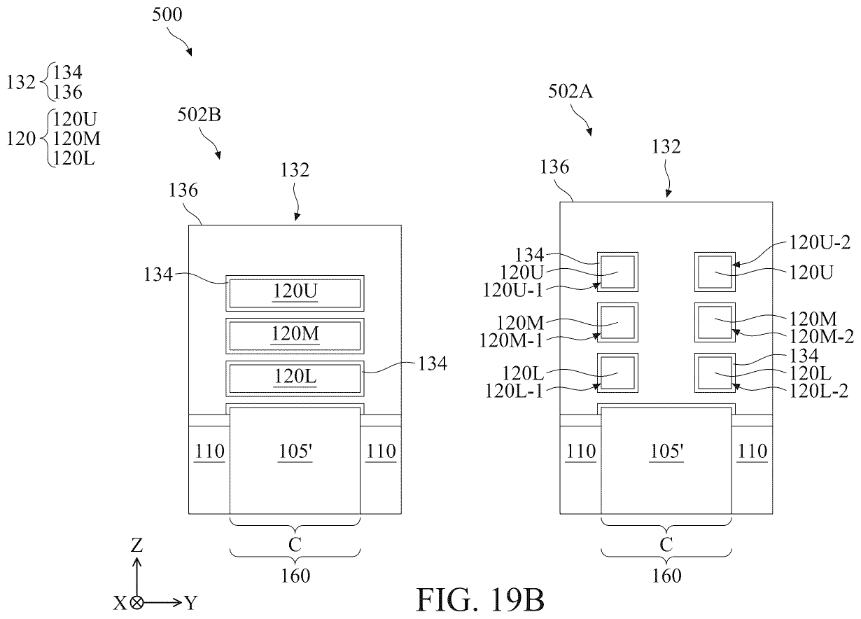

FIG. 18A, FIG. 18B, FIG. 19A, and FIG. 19B are diagrammatic cross-sectional views of a device 500, in portion or entirety, that may include transistors having segmented channels, such as a transistor 502A, and transistors having non-segmented channels, such as a transistor 502B, according to various aspects of the present disclosure. Transistor 502A may be configured as described herein, such as similar to transistor T. Transistor 502B may be configured as described herein, except channel segmentation is not performed when fabricating transistor 502B, such that transistor 502B includes semiconductor layers 120 without segmentation. In some embodiments, transistor 502A is a nanowire transistor, and transistor 502B is a nanosheet transistor. In FIG. 18A and FIG. 18B, transistor 502A and transistor 502B may be fabricated on a same wafer, and a height of transistor 502A may be substantially the same as a height of transistor 502B. In FIG. 19A and FIG. 19B, transistor 502A and transistor 502B may be fabricated on a same wafer with a same critical poly pitch (CPP), which generally refers to a distance between adjacent gates (e.g., gate structures 130). A height of transistor 502A may be different than a height of transistor 502B. In some embodiments, since transistor 502A (i.e., having a segmented channel as described herein) enables shorter gate lengths with better short channel effect control, transistor 502A may have source/drain structures 150 with larger volumes, which may reduce source/drain resistance and/or increase channel stress. The shorter gate length and/or higher channel height of transistor 502A may facilitate the larger volume source/drain structures 150. In some embodiments, channel width/height ratios of transistor 502A are less than about 2, and channel width/height ratios of transistor 502B are greater than or equal to about 2. FIG. 18A, FIG. 18B, FIG. 19A, and FIG. 19B have been simplified for the sake of clarity to better understand the inventive concepts of the present disclosure. Additional features may be added in device 500 of FIG. 18A, FIG. 18B, FIG. 19A, and FIG. 19B, and some of the features described below may be replaced, modified, or eliminated in other embodiments of device 500 of FIG. 18A, FIG. 18B, FIG. 19A, and FIG. 19B.

The present disclosure provides for many different embodiments. In some embodiments, a device structure includes a semiconductor ring and a gate. The gate is disposed over and engages the semiconductor ring. The semiconductor ring extends lengthwise along a first direction between a first source/drain and a second source/drain, and the gate is disposed between the first source/drain and the second source/drain along the first direction. The gate extends lengthwise along a second direction different than the first direction, and the gate extends through the semiconductor ring. In some embodiments, the semiconductor ring is disposed over a semiconductor base and the gate extends into the semiconductor base. In some embodiments, the semiconductor ring is a rectangular-shaped ring that surrounds a portion of the gate extending therethrough. In some embodiments, a portion of the gate extending through the semiconductor ring has a width along the second direction that is tapered from a top to a bottom of the semiconductor ring. In some embodiments, a portion of the gate extending through the semiconductor ring has a width along the second direction that is uniform from a top to a bottom of the semiconductor ring. In some embodiments, the gate is disposed over and engages a top, a bottom, an inner sidewall, and an outer sidewall of the semiconductor ring.

In some embodiments, the semiconductor ring includes a first semiconductor segment and a second semiconductor segment extending along the first direction from the first source/drain to the second source/drain, and the gate fills a spacing between the first semiconductor segment and the second semiconductor segment. In some embodiments, the semiconductor ring includes at least one third semiconductor segment extending along the second direction from the first semiconductor segment to the second semiconductor segment. In some embodiments, the semiconductor ring includes a width to height ratio of the first semiconductor segment and the second semiconductor segment that is less than about 2. In some embodiments, the first semiconductor segment is a first nanowire, and the second semiconductor segment is a second nanowire. In some embodiments, the at least one third semiconductor segment connects the first nanowire to the second nanowire.

In some embodiments, a device includes a channel layer and a gate. The channel layer extends along a first direction between a first source/drain and a second source/drain, and the gate is disposed between the first source/drain and the second source/drain. The gate is disposed over and engages the channel layer. The gate extends along a second direction different than the first direction. The gate further extends along a third direction through the channel layer, and the third direction is different than the first direction and the second direction. In some embodiments, the channel layer may be disposed over a semiconductor base, and a portion of the gate extending through the channel layer extends into the semiconductor base. In some embodiments, the channel layer has a length along the first direction, segments of the channel layer have a respective width along the second direction and a respective height along the third direction, and a ratio of the respective width to the respective height is greater than about 0.5 and less than about 2. In some embodiments, the gate includes a first portion and a second portion that extend along the third direction through the channel layer. In some embodiments, the channel layer includes a first segment disposed between the gate and the first source/drain and a second segment disposed between the gate and the second source/drain.

In some embodiments, a method includes receiving a device structure that includes a multilayer stack extending lengthwise along a first direction between a first source/drain and a second source/drain and a dummy gate disposed over the multilayer stack and between the first source/drain and the second source/drain. The dummy gate extends lengthwise along a second direction different than the first direction, and the multilayer stack includes semiconductor layers and sacrificial layers. The method further includes forming a channel cut in the dummy gate and the multilayer stack. The channel cut extends along a third direction through the dummy gate and the multilayer stack. The channel cut segments the semiconductor layers of the multilayer stack, and the third direction is different than the first direction and the second direction. The method further includes forming a gate stack in the channel cut. Forming the gate stack includes replacing a remainder of the dummy gate and a remainder of the sacrificial layers of the multilayer stack with the gate stack. In some embodiments, forming the channel cut includes removing a central portion of the multilayer stack to form an opening therein.

In some embodiments, the method further includes forming sacrificial plug in the channel cut before forming the gate stack and the forming the gate stack includes replacing the sacrificial plug with the gate stack. In some embodiments, forming the sacrificial plug includes depositing an oxide material and performing a planarization process. In some embodiments, the dummy gate includes a dummy gate bulk and a dummy gate dielectric. In some embodiments, the method further includes replacing the dummy gate bulk with an antireflective coating before forming the channel cut in the dummy gate and the multilayer stack. In such embodiments, forming the gate stack may include replacing a remainder of the antireflective coating and a remainder of the dummy gate dielectric with the gate stack. In some embodiments, the channel cut is a first channel cut and the method further includes forming a second channel cut in the dummy gate and the multilayer stack. The second channel cut extends along the third direction through the dummy gate and the multilayer stack, and the second channel cut further segments the semiconductor layers. The gate stack may be formed in the second channel cut.

In some embodiments, a method includes forming a fin structure that includes first semiconductor layers and second semiconductor layers alternately stacked over a substrate. The method further includes forming a dummy gate structure over the fin structure, forming source/drain trenches in the fin structure (e.g., on opposite sides of the dummy gate structure), and replacing the first semiconductor layers with dielectric interposers (e.g., sacrificial layers), and forming source/drain features in the source/drain trenches. The method further includes forming a dielectric layer over the dummy gate structure and the source/drain features and forming a first opening in the dielectric layer to expose a first portion of the dummy gate structure. The method further includes performing an etching process to etch the dummy gate structure, the first semiconductor layers, and the dielectric interposers through the first opening, so as to form a first trench extending through the dummy gate structure, the first semiconductor layers, and the dielectric interposers. The method further includes depositing an oxide material to fill the first trench. The method further includes removing the oxide material, remaining portions of the dummy gate structure, and remaining portions of the dielectric interposers to form a gate trench and depositing a conductive material in the gate trench to form a metal gate structure that wraps around the second semiconductor layers.

In some embodiments, the substrate is etched during the etching process, such that the trench extends into the substrate. In some embodiments, the etching process is performed until a bottommost one of the dielectric interposers is exposed, such that a bottom surface of the trench is separated from the substrate by the bottommost one of the dielectric interposers. In some embodiments, the method further includes forming a second opening in the dielectric layer to expose a second portion of the dummy gate structure, wherein the etching process etches the dummy gate structure, the first semiconductor layers, and the dielectric interposers through the first opening and the second opening, so as to form the first trench and a second trench extending through the dummy gate structure, the first semiconductor layers, and the dielectric interposers, respectively. In some embodiments, the fin structure extends in a first direction, and the dummy gate structure extends in a second direction different to the first direction the first direction (e.g., perpendicular to). In the second direction, a first width between the first trench and a first side of the fin structure may be the same as a second width between the second trench and a second side of the fin structure. In some embodiments, a third width between the first trench and the second trench is the same as the first width. In some embodiments, a third width between the first trench and the second trench is greater than or less than the first width.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device structure comprising:
an active region that includes a semiconductor ring, a first source/drain, and a second source/drain, wherein the active region extends lengthwise along a first direction and the semiconductor ring extends lengthwise along the first direction between the first source/drain and the second source/drain; and
a gate disposed over and engaging the semiconductor ring, wherein the gate extends through the semiconductor ring, the gate is disposed between the first source/drain and the second source/drain along the first direction, the gate extends lengthwise along a second direction different from the first direction, and the gate extends from over the semiconductor ring to over an isolation structure along the second direction.

2. The device structure of claim 1, wherein the semiconductor ring is disposed over a semiconductor base and the gate extends into the semiconductor base.

3. The device structure of claim 1, wherein the semiconductor ring is a quadrilateral-shaped ring that surrounds a portion of the gate extending therethrough.

4. The device structure of claim 1, wherein a portion of the gate extending through the semiconductor ring has a width along the second direction that is tapered from a top to a bottom of the semiconductor ring.

5. The device structure of claim 1, wherein a portion of the gate extending through the semiconductor ring has a width along the second direction that is uniform from a top to a bottom of the semiconductor ring.

6. The device structure of claim 1, wherein the gate is disposed over and engages a top, a bottom, an inner sidewall, and an outer sidewall of the semiconductor ring.

7. The device structure of claim 1, wherein the semiconductor ring includes:
a first semiconductor segment and a second semiconductor segment extending along the first direction from the first source/drain to the second source/drain, wherein the gate fills a spacing between the first semiconductor segment and the second semiconductor segment; and
at least one third semiconductor segment extending along the second direction from the first semiconductor segment to the second semiconductor segment.

8. The device structure of claim 7, wherein a width to height ratio of the first semiconductor segment and the second semiconductor segment is less than about 2.

9. The device structure of claim 7, wherein the first semiconductor segment is a first nanowire, the second semiconductor segment is a second nanowire, and the at least one third semiconductor segment connects the first nanowire to the second nanowire.

10. A method comprising:
forming an active region that includes a channel layer, a first source/drain, and a second source/drain, wherein the active region extends lengthwise along a first direction, the channel layer is disposed over a semiconductor base, and the channel layer extends lengthwise along the first direction between the first source/drain and the second source/drain; and
forming a gate that extends lengthwise along a second direction different from the first direction, wherein the gate is disposed between the first source/drain and the second source/drain along the first direction, the gate is disposed over and engages the channel layer, the gate extends along the second direction over the channel layer and an isolation structure, and the gate extends along a third direction through the channel layer, wherein the third direction is different from the first direction and the second direction.

11. The method of claim 10, wherein the forming of the channel layer and the forming of the gate is configured to provide the gate with a portion extending through the channel layer and into the semiconductor base.

12. The method of claim 10, wherein the forming of the channel layer is configured to provide the channel layer with segments having a respective width along the second direction and a respective height along the third direction, wherein a ratio of the respective width to the respective height is greater than about 0.5 and less than about 2.

13. The method of claim 10, wherein the forming of the channel layer and the forming of the gate is configured to provide the gate with a first portion and a second portion that extend along the third direction through the channel layer.

14. The method of claim 10, wherein the forming of the channel layer includes forming a first segment of the channel layer between the gate and the first source/drain and forming a second segment of the channel layer between the gate and the second source/drain.

15. A method comprising:
receiving a device structure that includes a multilayer stack extending lengthwise along a first direction between a first source/drain and a second source/drain and a dummy gate disposed over the multilayer stack and between the first source/drain and the second source/drain, wherein the dummy gate extends lengthwise along a second direction different than the first direction and the multilayer stack includes semiconductor layers and sacrificial layers;
forming a channel cut in the dummy gate and the multilayer stack, wherein the channel cut extends along a third direction through the dummy gate and the multilayer stack, wherein the channel cut segments the semiconductor layers of the multilayer stack and the third direction is different than the first direction and the second direction; and
forming a gate stack in the channel cut, wherein the forming of the gate stack includes replacing a remainder of the dummy gate and a remainder of the sacrificial layers of the multilayer stack with the gate stack, wherein the gate stack extends lengthwise along the second direction over the semiconductor layers of the multilayer stack and an isolation structure, wherein the gate stack includes a gate dielectric and a gate electrode.

16. The method of claim 15, wherein the method further includes:
forming sacrificial plug in the channel cut before forming the gate stack; and
the forming the gate stack includes replacing the sacrificial plug with the gate stack.

17. The method of claim 16, wherein the forming the sacrificial plug includes:
depositing an oxide material; and
performing a planarization process.

18. The method of claim 15, wherein the dummy gate includes a dummy gate bulk and a dummy gate dielectric and the method further includes:
replacing the dummy gate bulk with an antireflective coating before forming the channel cut in the dummy gate and the multilayer stack; and
the forming the gate stack includes replacing a remainder of the antireflective coating and a remainder of the dummy gate dielectric with the gate stack.

19. The method of claim 15, wherein the forming the channel cut includes removing a central portion of the multilayer stack to form an opening therein.

20. The method of claim 15, wherein:
the channel cut is a first channel cut; and
the method further includes:
forming a second channel cut in the dummy gate and the multilayer stack, wherein the second channel cut extends along the third direction through the dummy gate and the multilayer stack, wherein the second channel cut further segments the semiconductor layers, and
forming the gate stack in the second channel cut.
